(19) United States
(12) Patent Application Publication
(10) Pub. No.: US 2026/0006921 A1
(43) Pub. Date: Jan. 1, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Chih-Kuan YU, Nantou County (TW); Ping-Chieh CHIN, Tainan City (TW); Feng-Chi HUNG, Chu-Bei City (TW); Wen-I HSU, Tainan City (TW); Jen-Cheng LIU, Hsin-Chu City (TW)

(21) Appl. No.: 18/905,418

(22) Filed: Oct. 3, 2024

Related U.S. Application Data
(60) Provisional application No. 63/666,372, filed on Jul. 1, 2024.

(51) Int. Cl. H01L 27/146; H04N 25/59

(52) U.S. Cl. CPC H10F 39/18; H04N 25/59; H10F 39/014

(57) ABSTRACT

A control circuitry region of a pixel sensor of a semiconductor device includes a plurality of conversion gain circuits that may be selectively activated and/or deactivated in various combinations to enable a plurality of sequential conversion gain operations to be performed across an exposure operation of the semiconductor device. The control circuitry region may include a first conversion gain circuit and a second conversion gain circuit that are connected to a floating diffusion node of the pixel sensor in parallel. The selectable parallel conversion gain circuits enable sequential conversion gain operations to be performed for the pixel sensor such that the capacitance in the pixel sensor may be gradually increased through the conversion gain operations. Gradually increasing the capacitance in the pixel sensor across the sequential conversion gain operations provides for smaller signal-to-noise ratio (SNR) drops, which enables a low SNR drop to be achieved for the pixel sensor.

### CROSS-REFERENCE TO RELATED APPLICATION

This patent application claims priority to U.S. Provisional Patent Application No. 63/666,372, filed on Jul. 1, 2024, and entitled “SEMICONDUCTOR DEVICES AND METHODS OF FORMATION.” The disclosure of the prior application is considered part of and is incorporated by reference into this patent application.

### BACKGROUND

A complementary metal oxide semiconductor (CMOS) image sensor device may include a plurality of pixel sensors arranged in a pixel sensor array. A pixel sensor of the CMOS image sensor device may include a photodiode configured to convert photons of incident light to a photocurrent of electrons. The magnitude of the photocurrent is based at least in part on the intensity of the incident light.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2F are diagrams of an example implementation of an exposure operation for a pixel sensor described herein.

FIGS. 3A and 3B are diagrams of an example semiconductor device described herein.

FIGS. 4A-4C are diagrams of an example implementation of forming a semiconductor die (or a portion thereof) described herein.

FIGS. 5A-5D are diagrams of an example implementation of forming a semiconductor die (or a portion thereof) described herein.

FIGS. 6A and 6B are diagrams of an example implementation of forming a semiconductor device (or a portion thereof) described herein.

FIGS. 7A and 7B are diagrams of an example semiconductor device described herein.

FIGS. 8A-8D are diagrams of an example implementation of forming a semiconductor die (or a portion thereof) of the semiconductor device described herein.

FIGS. 9A-9E are diagrams of an example implementation of forming a semiconductor device (or a portion thereof) described herein.

FIGS. 10A and 10B are diagrams of an example implementation of forming a semiconductor device (or a portion thereof) described herein.

FIGS. 11A-11D are diagrams of example implementations of a semiconductor device described herein.

FIGS. 12A and 12B are diagrams of an example semiconductor device described herein.

FIGS. 13A-13N are diagrams of examples of another example implementation of a pixel sensor described herein.

FIG. 14 is a flowchart of an example process associated with forming a semiconductor device described herein.

FIG. 15 is a flowchart of an example process associated with forming a semiconductor device described herein.

FIG. 16 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition to a photodiode (e.g., a sensing region), a pixel sensor of an image sensor device (e.g., a complementary metal-oxide-semiconductor (CMOS) image sensor) may also include a control circuitry region. The control circuitry region is electrically connected to the photodiode and is configured to receive a photocurrent that is generated by the photodiode and to store the photocurrent in a floating diffusion node. The photocurrent in the floating diffusion node may be sampled and converted to a pixel sensor signal that can be used to generate an image and/or a video.

The control circuitry region may also include a conversion gain circuit that is configured to perform a plurality of conversion gain operations on the photocurrent to enable a high dynamic range (HDR) to be achieved for images and/or video generated by the image sensor device. Each conversion gain operation may include applying different levels of gain (e.g., a high conversion gain (HCG) operation with a high conversion gain, and a low conversion gain (LCG) operation with a low conversion gain) to the photocurrent to generate high and low pixel sensor signals that are then combined into a composite pixel sensor signal that has a high dynamic range.

However, a large signal-to-noise ratio (SNR) drop may occur in the composite pixel sensor signal between the HCG operation and the LCG operation. The SNR drop may result in increased noise in images and/or video generated by the image sensor device, which reduces the quality of the images and/or video generated by the image sensor device.

In some implementations described herein, a control circuitry region of a pixel sensor of a semiconductor device (e.g., a CMOS image sensor device) includes a plurality of conversion gain circuits that may be selectively activated and/or deactivated in various combinations to enable a plurality of sequential conversion gain operations to be performed across an exposure operation of the semiconductor device. For example, the control circuitry region may include a first conversion gain circuit and a second conversion gain circuit, both of which may be connected to a floating diffusion node in the control circuitry region.

The first and second conversion gain circuits may be deactivated for a first conversion gain operation (e.g., an HCG operation). The first conversion gain circuit may be deactivated and the second conversion circuit may be activated for a second conversion gain operation (e.g., a medium conversion gain (MCG) operation). The second conversion gain circuit may be deactivated and the first conversion circuit may be activated for a third conversion gain operation (e.g., a medium-low conversion gain (MLCG) operation). The first conversion gain circuit and the second conversion circuit may both be activated for a fourth conversion gain operation (e.g., an LCG operation).

The sequential conversion gain operations provide for a lower SNR drop between each of the conversion gain operations than would be the case if only an HCG operation and an LCG operation were performed. The reduced magnitude of the SNR drops between the sequential conversion gain operations may be achieved by using the first and second conversion gain circuits to gradually increase the capacitance in the control circuitry region through the sequential conversion gain operations. For example, the control circuitry region may have a first capacitance (e.g., the capacitance of the floating diffusion node) in the first conversion gain operation. The control circuitry region may have a second capacitance (e.g., the capacitance of the floating diffusion node plus the capacitance of the second conversion gain circuit), in the second conversion gain operation, that is greater than the first capacitance. The control circuitry region may have a third capacitance (e.g., the capacitance of the floating diffusion node plus the capacitance of the first conversion gain circuit), in the third conversion gain operation, that is greater than the second capacitance. The control circuitry region may have a fourth capacitance (e.g., the capacitance of the floating diffusion node plus the capacitance of the first and second conversion gain circuits), in the fourth conversion gain operation, that is greater than the third capacitance.

Gradually increasing the capacitance in the control circuitry region across the sequential conversion gain operations provides for smaller SNR drops than SNR drops that might otherwise occur if only an HCG operation and an LCG operation were performed. Thus, the first and second conversion gain circuits enable a low SNR drop to be achieved in a composite pixel sensor signal that is generated from the sequential conversion gain operations.

The low SNR drop may enable reduced noise in images and/or video generated by the semiconductor device to be achieved, which increases the quality of the images and/or video generated by the semiconductor device.

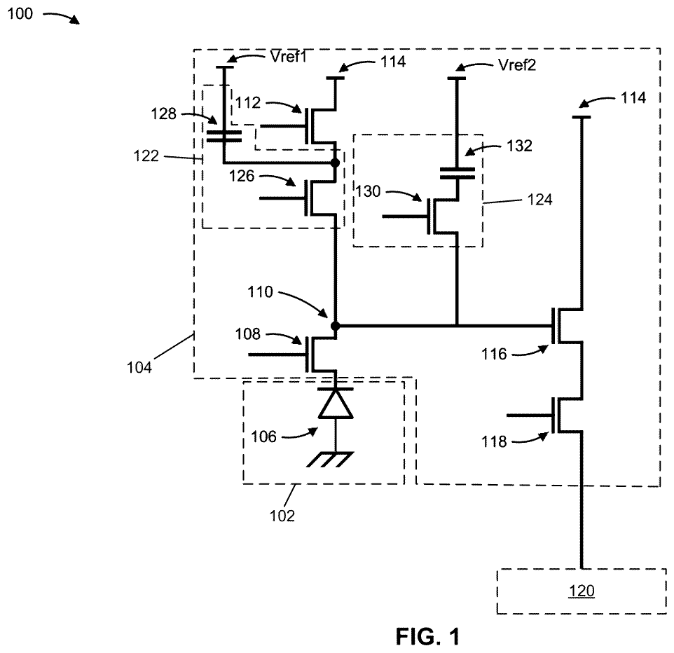

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

The pixel sensor 100 includes a sensing region 102 that may be configured to sense and/or accumulate incident light (e.g., light directed toward the pixel sensor 100). The pixel sensor 100 also includes a control circuitry region 104. The control circuitry region 104 is electrically connected with the sensing region 102 and is configured to receive a photocurrent that is generated by the sensing region 102. Moreover, the control circuitry region 104 is configured to transfer the photocurrent from the sensing region 102 to downstream circuits such as image processing circuits, among other examples.

The sensing region 102 includes a photodiode 106. The photodiode 106 may absorb and accumulate photons of the incident light, and may generate the photocurrent based on absorbed photons. The magnitude of the photocurrent is based on the amount of light collected in the photodiode 106. Thus, the accumulation of photons in the photodiode 106 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 106 is electrically connected with a source/drain of a transfer gate 108 of the control circuitry region 104. The transfer gate 108 is configured to control the transfer of the photocurrent from the photodiode 106 to a floating diffusion node 110. The photocurrent is provided from a source/drain (e.g., which may correspond to the photodiode 106) of the transfer gate 108 to another drain/drain of the transfer gate 108 (e.g., which may correspond to the floating diffusion node 110) based on selectively switching a gate of the transfer gate 108. The gate of the transfer gate 108 may be selectively switched by applying a transfer voltage (Vₜₓ) to the transfer gate 108. In some implementations, the transfer voltage being applied to the transfer gate 108 causes a conductive channel (e.g., a leakage path or buried channel) to form between the photodiode 106 and the floating diffusion node 110, which enables the photocurrent to propagate through the conductive channel from the photodiode 106 to the floating diffusion node 110. In some implementations, the transfer voltage being removed from the transfer gate 108 (or the absence of the transfer voltage) causes the conductive channel to be removed such that the photocurrent cannot pass from the photodiode 106 to the floating diffusion node 110.

The control circuitry region 104 further includes a reset transistor 112. The reset transistor 112 is electrically connected to a supply voltage source 114. The reset transistor 112 may be controlled by a reset voltage (Vrst) applied by the supply voltage source 114. The reset transistor 112 may be electrically coupled with the floating diffusion node 110. The reset voltage may be applied to the reset transistor 112 to pull the floating diffusion node 110 to a high voltage (e.g., to the supply voltage) to “reset” the floating diffusion node 110 (e.g., by draining any residual charge in the floating diffusion node 110) prior to activation of the transfer gate 108 to transfer the photocurrent from the photodiode 106 to the floating diffusion node 110.

The photocurrent may be used to apply a floating diffusion voltage (V_{fd}) to a source-follower gate 116 of the control circuitry region 104. This permits the photocurrent to be observed without removing or discharging the photocurrent from the floating diffusion node 110. The reset transistor 112 may instead be used to remove or discharge the photocurrent from the floating diffusion node 110.

The source-follower gate 116 functions as a high impedance amplifier for the pixel sensor 100. The source-follower gate 116 provides a voltage to current conversion of the floating diffusion voltage. The output of the source-follower gate 116 is electrically connected with a row-select gate 118, which is configured to control the flow of the photocurrent to an image processing circuit 120. The row-select gate 118 is controlled by selectively applying a select voltage (Vdi) to the gate of the row-select gate 118. This permits the photocurrent to flow to an output of the pixel sensor 100. The image processing circuit 120 may be a part of the pixel sensor 100 or may be a separate part of a semiconductor device in which the pixel sensor 100 and the image processing circuit 120 are included.

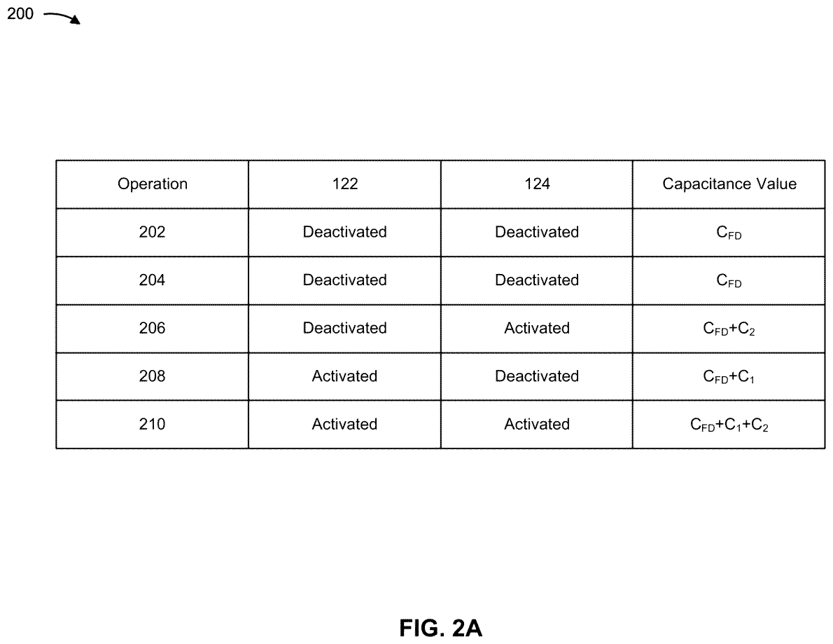

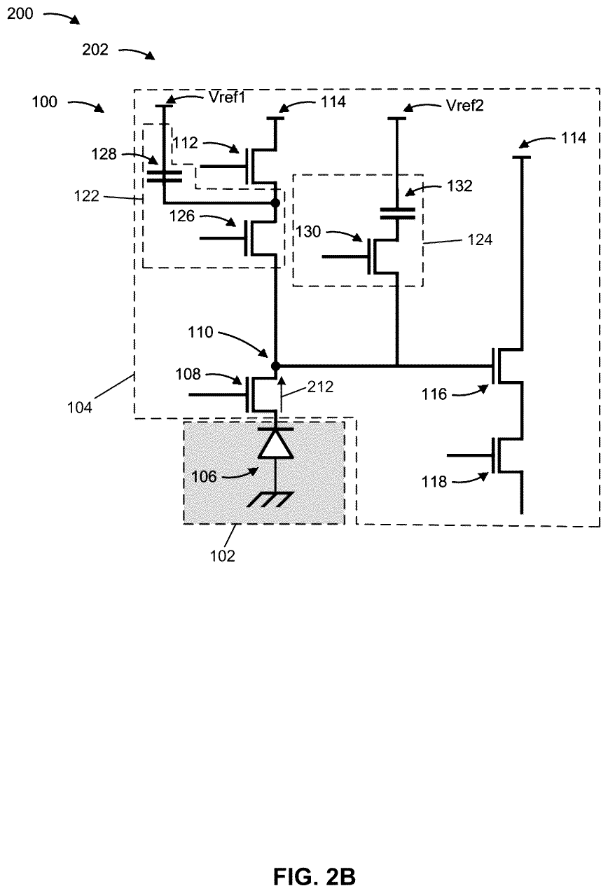

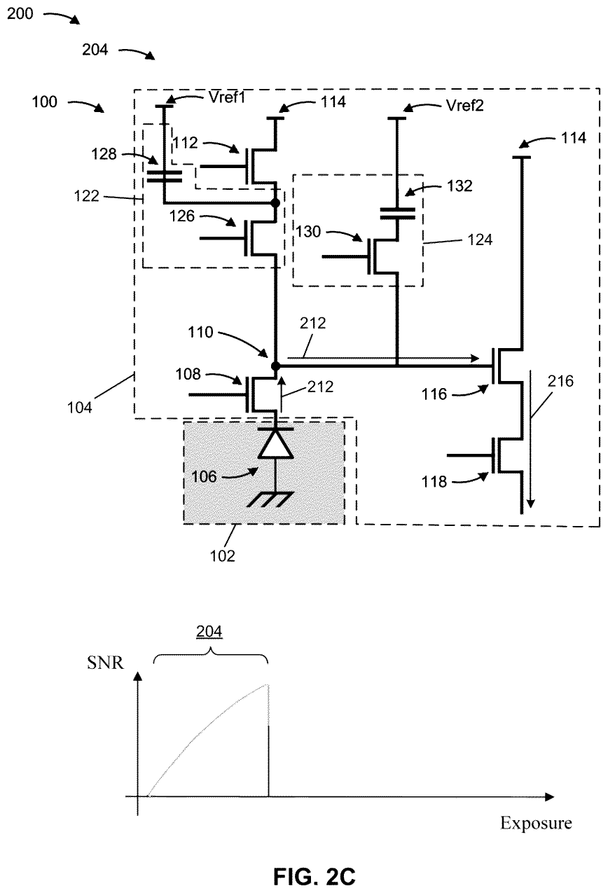

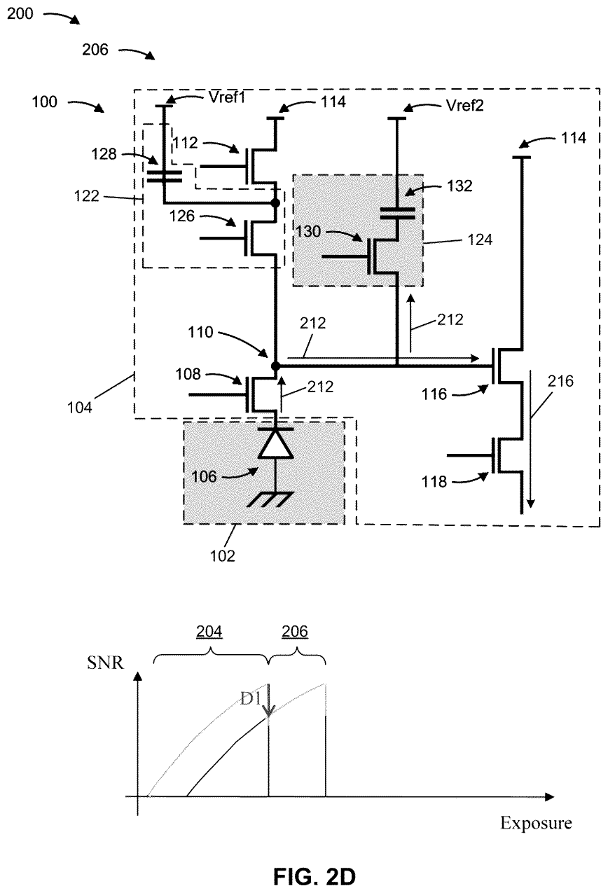

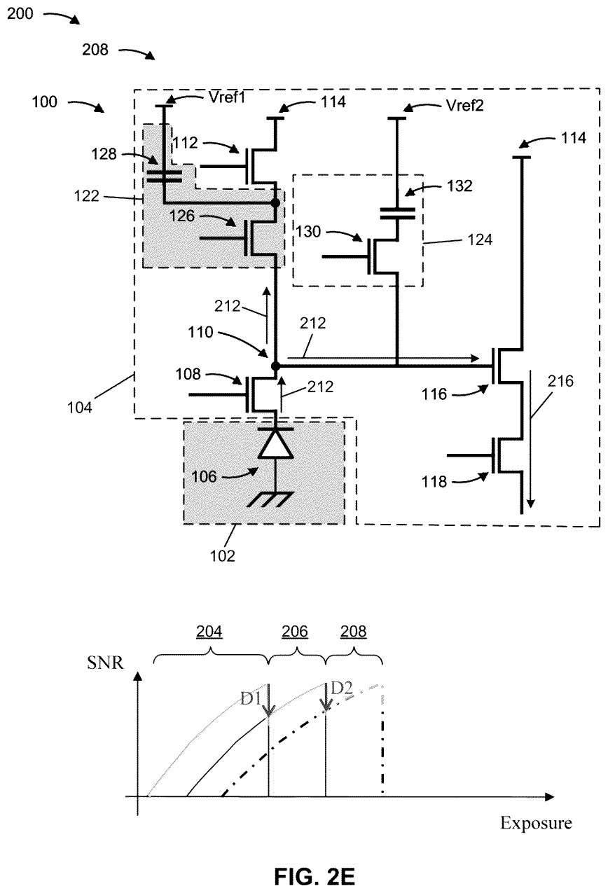

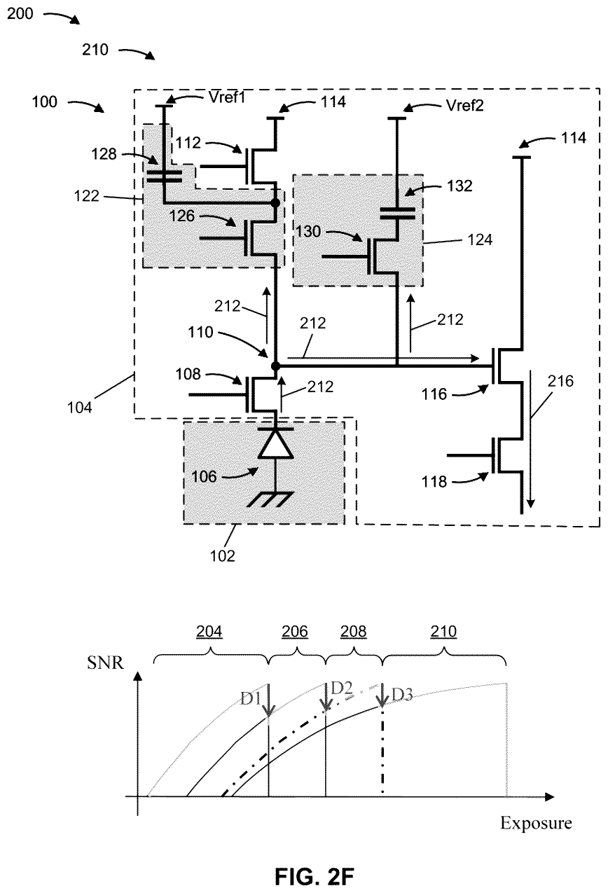

As further shown in FIG. 1, the control circuitry region 104 of the pixel sensor 100 includes a plurality of conversion gain circuits, including a conversion gain circuit 122 and a conversion gain circuit 124. The conversion gain circuits 122 and 124 can be selectively activated or deactivated in various combinations to enable a plurality of sequential conversion gain operations to be performed for an exposure operation of the pixel sensor 100 (e.g., an exposure operation to generate an image and/or a video). The conversion gain circuits 122 and 124 enable the capacitance of the pixel sensor 100 to be gradually increased through the exposure operation, which gradually increases the full-well capacity (FWC) of the pixel sensor 100. The increased capacitance enables additional charge to be stored in the control circuitry region 104 during the exposure operation, which enables the level of the photocurrent to be increased during the exposure operation. In this way, the conversion gain can be inversely decreased so that a high dynamic range can be achieved in the exposure operation. An example exposure operation in which a plurality of sequential conversion gain operations are performed by the pixel sensor 100 is illustrated and described in connection with FIGS. 2A-2F.

The conversion gain circuit 122 includes a conversion gain transistor 126 and a capacitor 128, and the conversion gain circuit 124 includes a conversion gain transistor 130 and a capacitor 132. A first source/drain terminal of the conversion gain transistor 126 is electrically coupled to the floating diffusion node 110, and a second source/drain terminal of the conversion gain transistor 126 is electrically coupled to the capacitor 128. The capacitor 128 is electrically coupled to a reference voltage source (Vref1). The capacitor 128 is electrically coupled to the floating diffusion node 110 through the conversion gain transistor 126.

A first source/drain terminal of the conversion gain transistor 130 is electrically coupled to the floating diffusion node 110, and a second source/terminal region of the conversion gain transistor 130 is electrically coupled to the capacitor 132. The capacitor 132 is electrically coupled to a reference voltage source (Vref2). The capacitor 132 is electrically coupled to the floating diffusion node 110 through the conversion gain transistor 130.

In some implementations, Vref1 and Vref2 may be the same reference voltage source. In some implementations, Vref1 and Vref2 may be different reference voltage sources. In some implementations, Vref1 and/or Vref2 may be the same as the supply voltage source 114. In some implementations, Vref1 and/or Vref2 may be different than the supply voltage source 114.

The conversion gain transistors 126 and 130 enable the conversion gain circuits 122 and 124 to be selectively activated or deactivated, respectively. For example, when the conversion gain transistor 126 is activated, the capacitor 128 may be connected to the floating diffusion node 110, thereby enabling the capacitor 128 to function as a lateral overflow integration capacitor (LOFIC) for the floating diffusion node 110. In particular, the capacitor 128 may store overflow charge from the floating diffusion node 110, thereby enabling additional charge generated by the photodiode 106 to be stored in the floating diffusion node 110 without the floating diffusion node 110 reaching saturation. When the conversion gain transistor 126 is deactivated, the capacitor 128 may be disconnected to the floating diffusion node 110.

Similarly, when the conversion gain transistor 130 is activated, the capacitor 132 may be connected to the floating diffusion node 110, thereby enabling the capacitor 132 to function as a LOFIC for the floating diffusion node 110. In particular, the capacitor 132 may store overflow charge from the floating diffusion node 110, thereby enabling additional charge generated by the photodiode 106 to be stored in the floating diffusion node 110 without the floating diffusion node 110 reaching saturation. When the conversion gain transistor 130 is deactivated, the capacitor 132 may be disconnected from the floating diffusion node 110.

The conversion gain transistors 126 and 130 are electrically coupled to the floating diffusion node 110 in parallel. Thus, the capacitor 128 and the capacitor 132 are electrically coupled to the floating diffusion node 110 and the supply voltage source 114 in parallel. The capacitance (C₁) of the capacitor 128 and the capacitance (C₂) of the capacitor 132 may be different, which enables various combinations (e.g., up to 4 combinations) of capacitance to be achieved in the pixel sensor 100 for the sequential conversion gain operations. In some implementations, the capacitance of the capacitor 128 is greater than the capacitance of the capacitor 132. In some implementations, the capacitance of the capacitor 132 is greater than the capacitance of the capacitor 128. In some implementations, additional conversion gain circuits that are similarly arranged may be included in the control circuitry region 104 of the pixel sensor 100 to enable greater than 4 combinations of capacitances to be selected for the sequential conversion gain operations.

The capacitor 128 and the reset transistor 112 may be electrically coupled to the second source/drain terminal of the conversion gain transistor 126 and to the supply voltage source 114 in parallel. The floating diffusion node 110 may be reset by activating the conversion gain transistor 126 and the reset transistor 112.

As indicated above, FIG. 1 is provided as an example. Other examples may differ from what is described with regard to FIG. 1.

FIGS. 2A-2F are diagrams of an example implementation 200 of an exposure operation for a pixel sensor 100 described herein. In the exposure operation, a plurality of sequential conversion gain operations are performed to achieve a high dynamic range for the exposure operation.

As shown in FIG. 2A, a charge transfer operation 202 may be initiated with the conversion gain circuits 122 and 124 of the pixel sensor 100 deactivated. The plurality of sequential conversion gain operations may include an HCG operation 204, an MCG operation 206, an MLCG operation 208, and an LCG operation 210. While the order of the sequential conversion operations is described in example implementation 200 as being HCG operation 204→MCG operation 206→MLCG operation 208→LCG operation 210, the sequential conversion gain operations may be performed in another order.

As further shown in FIG. 2A, the capacitance value for the pixel sensor 100 may be variable throughout the exposure operation. The conversion gain circuits 122 and 124 may both be deactivated during the charge transfer operation 202 and during the HCG operation 204. Thus, the capacitance value of the pixel sensor 100 may correspond to the capacitance (C_{FD}) of the floating diffusion node 110 of the pixel sensor 100. The conversion gain circuit 124 may be activated (and the conversion gain circuit 122 may remain deactivated) during the MCG operation 206, resulting in the capacitance value of the pixel sensor 100 corresponding to a combination of the capacitance of the floating diffusion node 110 and the capacitance of the capacitor 132 (C_{FD})+C₂). Thus, the capacitance value of the pixel sensor 100 may be greater during the MCG operation 206 than during the HCG operation 204. The conversion gain in the exposure operation is inversely proportional to the capacitance value of the pixel sensor 100. Thus, the conversion gain of the MCG operation 206 may be less than the conversion gain for the HCG operation 204.

The conversion gain circuit 122 may be activated (and the conversion gain circuit 124 may remain deactivated) during the MLCG operation 208, resulting in the capacitance value of the pixel sensor 100 corresponding to a combination of the capacitance of the floating diffusion node 110 and the capacitance of the capacitor 128 (C_{FD})+C₁). Thus, the capacitance value of the pixel sensor 100 may be greater during the MLCG operation 208 than during the HCG operation 204. As indicated above, the capacitance of the capacitor 128 may be greater than the capacitance of the capacitor 132 (e.g., C₁>C₂). Accordingly, the capacitance value of the pixel sensor 100 may be greater during the MLCG operation 208 than during the MCG operation 206. The conversion gain of the MLCG operation 208 may be less than the conversion gain for the HCG operation 204 and the conversion gain for the MCG operation 206.

The conversion gain circuits 122 and 124 may both be activated during the LCG operation 210, resulting in the capacitance value of the pixel sensor 100 corresponding to a combination of the capacitance of the floating diffusion node 110, the capacitance of the capacitor 128, and the capacitance of the capacitor 132 (C_{FD}+C₁+C₂). Thus, the capacitance value of the pixel sensor 100 may be greater during the LCG operation 208 than during the HCG operation 204, the MCG operation 206, and the MLCG operation 208. The conversion gain of the LCG operation 208 may be less than the conversion gain for the HCG operation 204, the conversion gain for the MCG operation 206, and the conversion gain for the MLCG operation 208.

As shown in FIG. 2B, the charge transfer operation 202 may be initiated such that a photocurrent 212 is provided through the transfer gate 108 to the floating diffusion node 110 during the exposure operation. The charge transfer operation 202 may be initiated by applying a transfer voltage (Vₜₓ) to the transfer gate 108, which enables the photocurrent 212 to flow from the photodiode 106 to the floating diffusion node 110.

As shown in FIG. 2C, the HCG operation 204 may include providing the photocurrent 212 to the gate of the source-follower gate 116, which converts the photocurrent 212 to an output signal 216 (e.g., a composite output signal). The SNR of the output signal 216 gradually increases during the HCG operation 204 as charge is accumulated in the floating diffusion node 110.

As shown in FIG. 2D, the MCG operation 206 may include activating the conversion gain circuit 124. To activate the conversion gain circuit 124, a voltage may be applied to the gate of the conversion gain transistor 130, which enables the photocurrent 212 to flow to the capacitor 132, which stores additional charge of the photocurrent 212. This expands the FWC of the pixel sensor 100 in that the charge of the photocurrent 212 is accumulated in the floating diffusion node 110 and in the capacitor 132. The SNR of the output signal 216 drops initially in the MCG operation 206 (e.g., by an SNR drop D1) due to the expanded FWC by activating the conversion gain circuit 124. The SNR increases during the MCG operation 206 as additional charge of the photocurrent 212 is stored in the capacitor 132.

As shown in FIG. 2E, the MLCG operation 208 may include deactivating the conversion gain circuit 124 and activating the conversion gain circuit 122. To deactivate the conversion gain circuit 124, the voltage may be removed from the gate of the conversion gain transistor 130, which prevents additional charge from flowing to the capacitor 132. To activate the conversion gain circuit 122, a voltage may be applied to the gate of the conversion gain transistor 126, which enables the photocurrent 212 to flow to the capacitor 128, which stores additional charge of the photocurrent 212. This expands the FWC of the pixel sensor 100 in that the charge of the photocurrent 212 is accumulated in the floating diffusion node 110 and in the capacitor 128. The SNR of the output signal 216 drops initially in the MLCG operation 208 (e.g., by an SNR drop D2) due to the greater capacitance of the capacitor 128 as compared to the capacitance of the capacitor 132. The SNR increases during the MLCG operation 208 as additional charge of the photocurrent 212 is stored in the capacitor 128.

As shown in FIG. 2F, the LCG operation 210 may include activating the conversion gain circuit 124 such that the conversion gain circuits 122 and 124 are both activated. This enables the photocurrent 212 to flow to both the capacitor 128 and the capacitor 132, which store additional charge of the photocurrent 212. This expands the FWC of the pixel sensor 100 in that the charge of the photocurrent 212 is accumulated in the floating diffusion node 110 and in the capacitors 128 and 132. The SNR of the output signal 216 drops initially in the LCG operation 210 (e.g., by an SNR drop D3) due to the expanded FWC by activating both conversion gain circuits 122 and 124. The SNR increases during the LCG operation 210 as additional charge of the photocurrent 212 is stored in the capacitors 128 and 132.

As indicated above, FIGS. 2A-2F are provided as an example. Other examples may differ from what is described with regard to FIGS. 2A-2F.

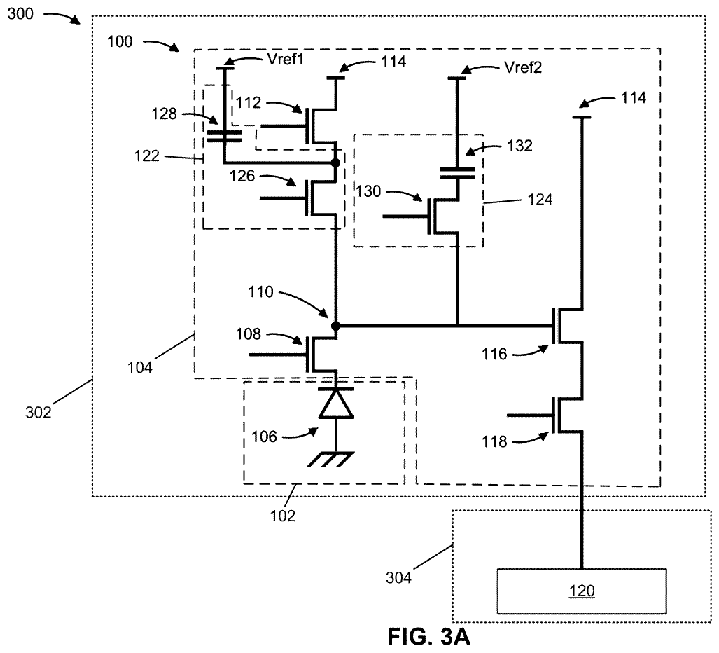

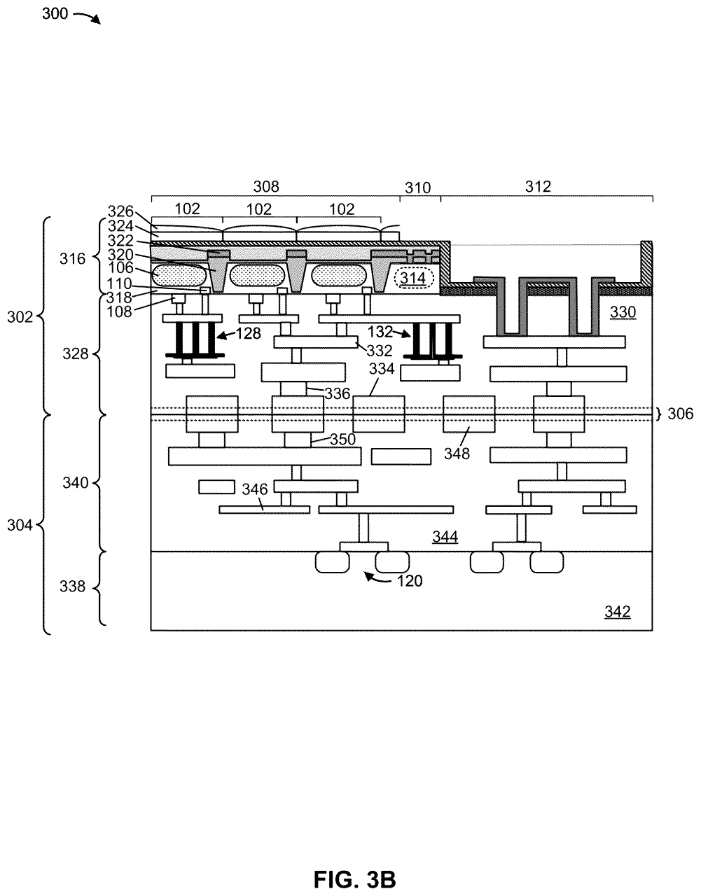

FIGS. 3A and 3B are diagrams of an example semiconductor device 300 described herein. The semiconductor device 300 includes an image sensor device such as a CMOS image sensor device that includes one or more pixel sensors 100. FIG. 3A illustrates an example distribution of components across a plurality of semiconductor dies of the semiconductor device 300. FIG. 3B illustrates a cross-sectional view of a structural implementation of the semiconductor device 300.

As shown in FIG. 3A, the pixel sensor 100, including the sensing region 102 and the control circuitry region 104, may be included on a semiconductor die 302. The semiconductor die 302 may be an image sensor die of the semiconductor device 300. The image processing circuit 120 may be included on a semiconductor die 304. The semiconductor die 304 may be an image sensor processing (ISP) die.

As shown in FIG. 3B, the semiconductor dies 302 and 304 may be vertically stacked or vertically arranged in the semiconductor device 300. The semiconductor die 302 and the semiconductor die 304 may be bonded at a bonding interface 306. Thus, the semiconductor device 300 may be a three-dimensional (3D) CMOS image sensor (3D CIS) because of the vertical arrangement of the semiconductor dies 302 and 304. The bond between the semiconductor dies 302 and 304 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 302 and 304 by forming metal-to-metal bonds and/or dielectric-to-dielectric bonds at the bonding interface 306 between the semiconductor dies 302 and 304.

The semiconductor die 302 may include a pixel sensor array 308, a black level correction (BLC) region 310 adjacent to (e.g., horizontally adjacent to) the pixel sensor array 308, and a bonding pad region 312 adjacent to (e.g., horizontally adjacent to) the BLC region 310, among other examples. In some implementations, the semiconductor die 302 includes additional lateral regions, such as a seal ring region and/or a scribe line region, among other examples.

The pixel sensor array 308 includes a plurality of sensing regions 102 of a plurality of pixel sensors 100. The sensing regions 102 of the pixel sensors 100 may be arranged in a grid or in another type of arrangement, and may be configured to generate photocurrents based on photons of incident light. The BLC region 310 may include a region 314 in a device layer 316 of the semiconductor die 302 that is shielded from incident light by a metal shielding layer. The metal shielding layer may be included as a light-blocking layer to prevent incident light from entering the region 314. The region 314 is thus a sensing region that is kept “dark” so that dark current measurements may be performed in the BLC region 310. A dark current measurement may be performed to measure the amount of charge (dark current) in the device layer 316 that is generated from sources other than incident light (e.g., from thermal energy in the device layer 316) so that the dark current measurement may be used for black level correction (or black level calibration) for the pixel sensor array 308. The bonding pad region 312 may include a bonding pad structure that enables an external electrical connection to be formed with the semiconductor device 300.

The device layer 316 includes a substrate layer 318. The substrate layer 318 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material.

Photodiodes 106 of the sensing regions 102 of the pixel sensors 100 are included in the substrate layer 318 of the semiconductor die 302. The photodiodes 106 may each include one or more doped regions of substrate layer 318. The substrate layer 318 may be doped with a plurality of types of ions to form a p-n junction or a PIN junction (e.g., a junction between a p-type portion, an intrinsic (or undoped) type portion, and an n-type portion) corresponding to a photodiode 106. For example, the substrate layer 318 may be doped with an n-type dopant to form a first portion (e.g., an n-type portion) of a photodiode 106 and a p-type dopant to form a second portion (e.g., a p-type portion) of the photodiode 106. A photodiode 106 may be configured to absorb photons of incident light. The absorption of photons causes the photodiode 106 to accumulate a charge (a photocurrent) due to the photoelectric effect. Here, photons bombard the photodiode 106, which causes emission of electrons of the photodiode 106. The emission of electrons causes the formation of electron-hole pairs, where the electrons migrate toward the cathode of the photodiode 106 and the holes migrate toward the anode, which produces the photocurrent.

The photodiodes 106 may be electrically isolated and/or optically isolated from one another by one or more isolation structures in the substrate layer 318. For example, a deep trench isolation (DTI) structure 320 may extend into the substrate layer 318 from a back side of the substrate layer 318. The DTI structure 320 may include elongated structures that include one or more dielectric layers, one or more metal layers, and/or another arrangement of layers and/or materials. The DTI structure 320 may laterally surround the photodiodes 106 of the pixel sensors 100 in the substrate layer 318.

A grid structure 322 may be included above the back side of the substrate layer 318. Sections of the grid structure 322 may be located over the DTI structure 320 and may be formed around the perimeter of the photodiodes 106 of the sensing regions 102 of the pixel sensors 100. Openings in the grid structure 322 are included above the photodiodes 106 to enable incident light to pass through the metal grid structure 322 and to the photodiodes 106. In some implementations, the grid structure 322 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples. In some implementations, the grid structure 322 may be formed of a dielectric material. In some implementations, the grid structure 322 is a multi-layer structure that includes one or more metal layers and/or one or more dielectric layers that are vertically stacked.

Color filter regions 324 of the sensing regions 102 of the pixel sensors 100 may be included in the openings in the grid structure 322. The color filter regions 324 may be included above the photodiodes 106 of the sensing regions 102 of the pixel sensors 100. The color filter regions 324 may be included above the photodiodes 106. Each color filter region 324 may be configured to filter incident light to allow a particular wavelength of the incident light to pass to a photodiode 106. For example, a color filter region 324 may filter incident light to allow red light to pass through the color filter region 324 to an associated photodiode 106. As another example, a color filter region 324 may filter incident light to allow green light to pass through the color filter region 324 to an associated photodiode 106. As another example, a color filter region 324 may filter incident light to allow blue light to pass through the color filter region 324 to an associated photodiode 106. In some implementations, a color filter region 324 may be non-discriminating or non-filtering, which may define a white pixel sensor. A non-discriminating or non-filtering color filter region 324 may include a material that permits all wavelengths of light to pass into the associated photodiode 106 (e.g., for purposes of determining overall brightness to increase light sensitivity for the image sensor). In some implementations, a color filter region 324 may be a near infrared (NIR) bandpass color filter region 324, which may define an NIR pixel sensor. An NIR bandpass color filter region 324 may include a material that permits the portion of incident light in an NIR wavelength range to pass to an associated photodiode 106 while blocking visible light from passing.

Micro-lenses 326 may be included over and/or on the color filter regions 324. The micro-lenses 326 may include a respective micro-lens for each of the sensing regions 102 of the pixel sensors 100. A micro-lens 326 may be formed to focus incident light toward a photodiode 106 of a sensing region 102 of a pixel sensor 100.

Transfer gates 108 of the pixel sensors 100 are included on the front side of the substrate layer 318. The transfer gates 108 are configured to selectively control the flow of photocurrents from the photodiodes 106 to floating diffusion nodes 110 of the pixel sensors 100. The floating diffusion nodes 110 may also be included in the substrate layer 318. A transfer gate 108 may selectively control the flow of a photocurrent from a photodiode 106 of a pixel sensor 100 to a floating diffusion node 110 of the pixel sensor 100 by selectively controlling a leakage path (e.g., a buried channel) between the photodiode 106 and the floating diffusion node 110 in the substrate layer 318. When a gate voltage (e.g., a transfer voltage (Vₜₓ)) is applied to the transfer gate 108, the leakage path may be formed in the substrate layer 318, thereby enabling a photocurrent to flow from the photodiode 106 to the floating diffusion node 110. When the gate voltage is removed, the leakage path is closed, thereby preventing the photocurrent from floating from the photodiode 106 to the floating diffusion node 110.

Not shown in FIG. 3B are additional components of the control circuitry regions 104 of the pixel sensors 100 that may be included in the substrate layer 318. Such components may include, for example, the reset transistors 112, the source-follower gates 116, the row-select gates 118, the conversion gain transistors 126 of the conversion gain circuits 122, and/or the conversion gain transistors 130 of the conversion gain circuits 124, among other examples.

The semiconductor die 302 may include an interconnect layer 328 vertically adjacent to the device layer 316. The interconnect layer 328 may include a dielectric region 330 that includes one or more dielectric layers. The dielectric layers may include backend dielectric layers (e.g., interlayer dielectric (ILD) layers, intermetal dielectric (IMD) layers) and etch stop layers (ESLs)) that are arranged in a direction that is approximately orthogonal to the substrate layer 318. The dielectric regions 330 may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 328 may further include a plurality of conductive structures 332 (e.g., electrically conductive structures) in the dielectric region 330. The conductive structures 332 are electrically coupled and/or physically coupled to the transfer gates 108, the floating diffusion nodes 110, and/or other structures of the pixel sensors 100 in the device layer 316. Moreover, the conductive structures 332 may be electrically interconnected together in the interconnect layer 328. The conductive structures 332 correspond to circuit routing that enables signals and/or power to be provided to and/or from components of the pixel sensors 100 in the device layer 316. The conductive structures 332 may include a combination of conductive structures that extend primarily horizontally in the interconnect layer 328 (e.g., trenches, conductive lines) and that are interconnected by interconnect structures (e.g., vias) that extend primarily vertically in the interconnect layer 328. The conductive structures 332 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 328 may be arranged in a vertical manner to facilitate electrical signals and/or power to be routed between the device layer 316 and the semiconductor die 304, between integrated circuit devices in the device layer 316 through the interconnect layer 328, and/or between the integrated circuit devices in the device layer 316 and integrated circuit devices in the semiconductor die 304. The conductive structures 332 may be arranged in alternating layers of metallization layers (referred to as “M”-layers) and via layers (referred to as “V”-layers). Each metallization layer may include one or more conductive structures laterally arranged in the interconnect layer 328, and each via layer may include one or more interconnect structures that interconnect the metallization layers in the interconnect layer 328. As an example, a metal-0 (M0) layer may be located at the bottom of the interconnect layer 328 and may be coupled to the integrated circuit devices (e.g., the transfer gates 108, the floating diffusion nodes 110) in the device layer 316, a via-0 (V0) layer may be located above and coupled to the M0 layer in the interconnect layer 328, a metal-1 (M1) layer may be located above and coupled to the V0 layer in the interconnect layer 328, a via-1 (V1) layer may be located above and coupled to the M1 layer in the interconnect layer 328, a metal-2 (M2) layer may be located above and electrically coupled to the V1 layer in the interconnect layer 328, and so on. In some implementations, the interconnect layer 328 includes nine (9) stacked metallization layers (e.g., M0-M8). In other implementations, the contact layer (referred to as “CO”-layer) may be located at the bottom of the interconnect layer 328 and may be directly coupled to the integrated circuit devices (e.g., with the transfer gates 108, with the floating diffusion nodes 110) in the device layer 316, a metal-1 (M1) layer may be located above and coupled to the CO layer in the interconnect layer 328, and so on. In some implementations, the interconnect layer 328 includes another quantity of stacked metallization layers.

The capacitors 128 of the conversion gain circuits 122 of the pixel sensors 100 may be included in the interconnect layer 328 of the semiconductor die 302. Additionally and/or alternatively, one or more of the capacitors 128 may be included in the device layer 316 (e.g., in the substrate layer 318) of the semiconductor die 302. The capacitors 132 of the conversion gain circuits 124 of the pixel sensors 100 may be included in the interconnect layer 328 of the semiconductor die 302. Additionally and/or alternatively, one or more of the capacitors 132 may be included in the device layer 316 (e.g., in the substrate layer 318) of the semiconductor die 302.

The capacitors 128 and 132 may be electrically coupled to the floating diffusion nodes 110 of the pixel sensors 100 in parallel through one or more conductive structures 332 in the interconnect layer 328. The capacitors 128 and 132 may be implemented as various types of capacitor structures, such as planar capacitor structures, trench capacitor structures, deep trench capacitor (DTC) structures, and/or another type of capacitor structures.

At the bonding interface 306 between the semiconductor dies 302 and 304, the interconnect layer 328 may include a plurality of bonding pads 334. The bonding pads 334 may be electrically coupled to the conductive structures 332 in the interconnect layer 328 by bonding vias 336 and/or other types of conductive structures. The bonding pads 334 and the bonding vias 336 may each include tungsten (W), cobalt (Co), ruthenium (Ru), titanium (Ti), aluminum (Al), copper (Cu), gold (Au), and/or a combination thereof, among other examples of electrically conductive metals.

The semiconductor die 304 may include one or more components of the image processing circuits 120 coupled to the pixel sensors 100 of the semiconductor device 300. The semiconductor die 304 may include a device layer 338 and an interconnect layer 340 vertically adjacent to the device layer 338. The device layer 338 may include a substrate layer 342, and one or more components of the image processing circuits 120 may be included in and/or on the substrate layer 342. The substrate layer 342 may include a silicon (Si) substrate, an SOI substrate, and/or another type of substrate. The image processing circuits 120 may include integrated circuit devices such as transistor structures (e.g., planar transistors, fin field effect transistors (finFETs), nanostructure transistors (e.g., nanosheet transistors, gate all around (GAA) transistors), capacitor structures, resistor structures, inductor structures, and/or other types of semiconductor structures).

The interconnect layer 340 may include a similar combination and/or arrangement of structures and/or layers as the interconnect layer 328 of the semiconductor die 302. For example, the interconnect layer 340 may include a dielectric region 344 (similar to the dielectric region 330) and a combination of conductive structures 346 (similar to the conductive structures 332) in the dielectric region 344. Moreover, the interconnect layer 340 may include bonding pads 348 that are electrically coupled to one or more of the conductive structures 346 by bonding vias 350. These layers and/or structures may have a reversed vertical arrangement relative to the semiconductor die 302, which enables the semiconductor die 302 and the semiconductor die 304 to be bonded at the bonding interface 306 such that the interconnect layer 328 and the interconnect layer 340 are facing each other and bonded together.

At the bonding interface 306, the bonding pads 334 of the semiconductor die 304 and bonding pads 348 of the semiconductor die 304 are directly bonded by metal-to-metal bonds. Moreover, the dielectric region 330 of the semiconductor die 302 and the dielectric region 344 of the semiconductor die 304 are directly bonded by dielectric-to-dielectric bonds.

As indicated above, FIGS. 3A and 3B are provided as an example. Other examples may differ from what is described with regard to FIGS. 3A and 3B.

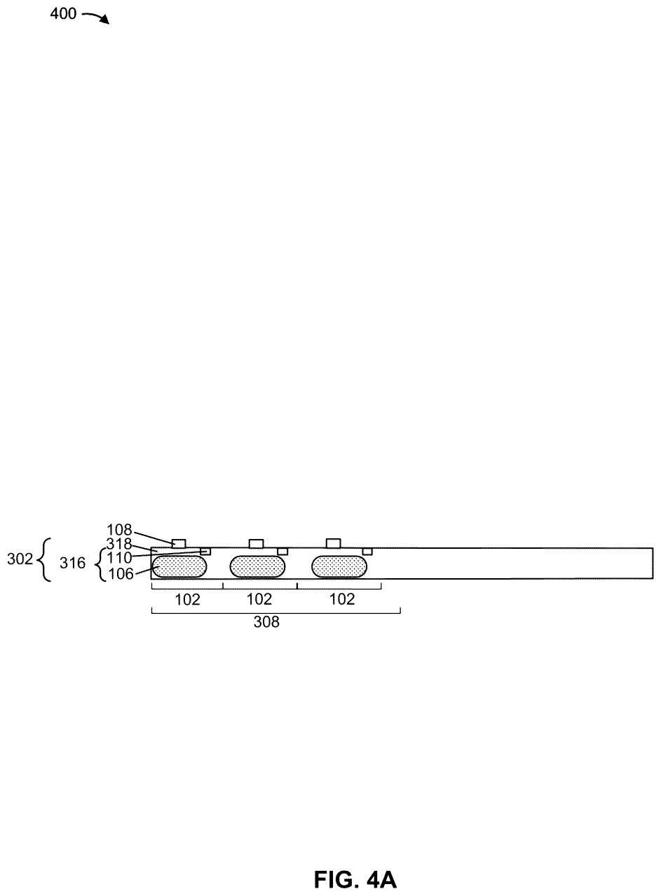

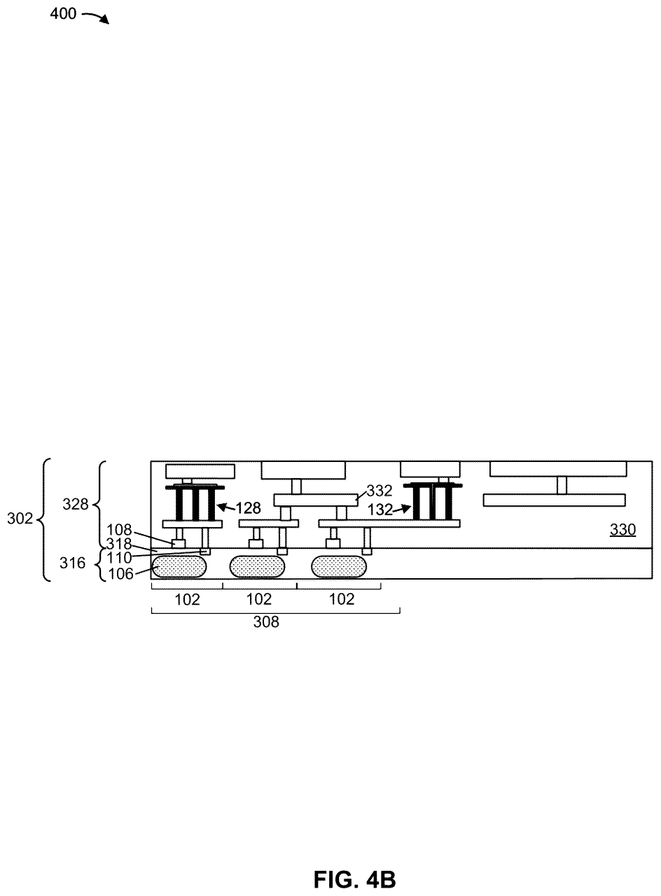

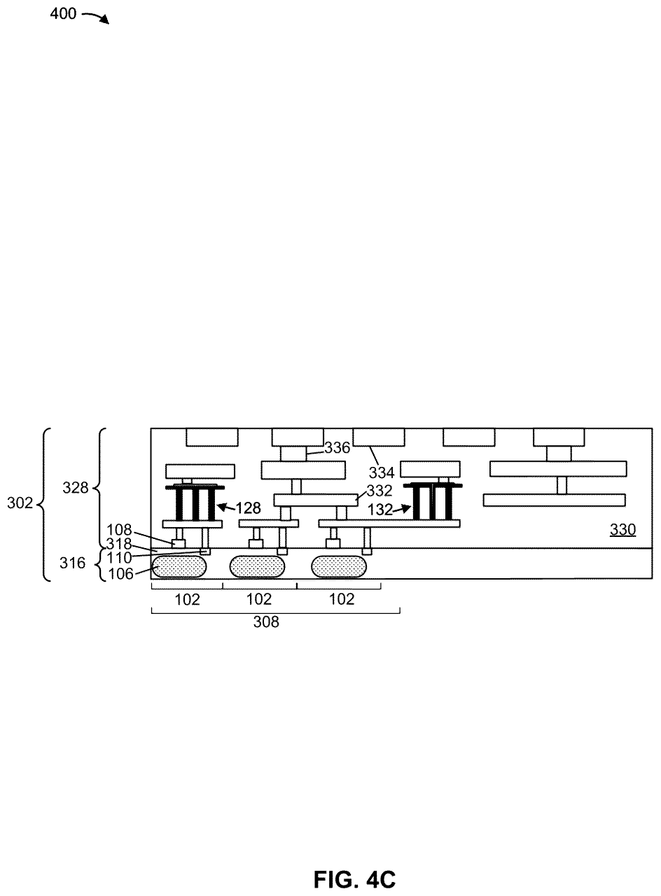

FIGS. 4A-4C are diagrams of an example implementation 400 of forming the semiconductor die 302 (or a portion thereof) described herein. In some implementations, one or more of the semiconductor processing operations described in connection with FIGS. 4A-4C may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 4A, the substrate layer 318 of the device layer 316 of the semiconductor die 302 is provided. The substrate layer 318 may be provided in the form of a semiconductor wafer such as a silicon (Si) wafer may be provided as an SOI wafer, and/or another type of semiconductor work piece.

As further shown in FIG. 4A, photodiodes 106 of the sensing regions 102 of the pixel sensors 100 of the pixel sensor array 308 may be formed in the substrate layer 318 of the semiconductor die 302. The photodiodes 106 may be formed from the front side of the substrate layer 318. In some implementations, an ion implantation tool may be used to implant ions into the substrate layer 318 to form a P-N junction between a p-doped region of the substrate layer 318 and an n-doped region of the substrate layer 318, or to form a P-I-N junction between p-doped region of the substrate layer 318, an n-doped region of the substrate layer 318, and an intrinsic (e.g., undoped) semiconductor region for a photodiode 106.

As further shown in FIG. 4A, additional regions of the substrate layer 318 may be doped to form the floating diffusion nodes 110. Transfer gates 108 of the pixel sensors 100 may be formed over and/or on the front side surface of the substrate layer 318. Forming transfer gates 108 may include depositing a gate dielectric on the front side surface of the substrate layer 318, depositing a gate electrode on the gate dielectric layer, and/or forming sidewall spacers on sidewalls of the gate electrode, among other examples. Additional structures of the control circuitry regions 104 of the pixel sensors may be formed in and/or on the substrate layer 318 in a similar manner. Such additional structures may include the reset transistors 112, the source-follower gates 116, the row-select gates 118, the conversion gain transistors 126 of the conversion gain circuits 122, and/or the conversion gain transistors 130 of the conversion gain circuits 124, among other examples. The reset transistors 112, the source-follower gates 116, the row-select gates 118, the conversion gain transistors 126 of the conversion gain circuits 122, and/or the conversion gain transistors 130 of the conversion gain circuits 124 may be implemented as various types of transistor structures, including planar transistors, finFETs, and/or nanostructure transistors, among other examples.

As in FIG. 4B, the dielectric region 330 of the interconnect layer 328 of the semiconductor die 302 may be formed over the front side of the substrate layer 318. The conductive structures 332 may be formed in the dielectric region 330.

A deposition tool may be used to deposit the dielectric region 330 using a physical vapor deposition (PVD) technique, an atomic layer deposition (ALD) technique, a chemical vapor deposition (CVD) technique, an oxidation technique, and/or another suitable deposition technique. The dielectric region 330 may be deposited as one or more dielectric layers. In some implementations, a planarization tool may be used to perform a planarization operation (e.g., a chemical mechanical planarization (CMP) operation) to planarize the one or more layers of the dielectric region 330 after the one or more layers of the dielectric region 330 are deposited.

A deposition tool may be used to deposit the conductive structures 332 using a PVD technique, a CVD technique, an ALD technique, an electroplating technique, and/or another suitable deposition technique. In some implementations, a seed layer may be deposited, and a conductive structure 332 may be deposited on the seed layer. In some implementations, a liner may be deposited, and a conductive structure 332 may be deposited on the liner. The liner may include a barrier liner, a diffusion liner, an adhesion liner, and/or another type of liner. Examples of such liners may include a tantalum nitride (TaN) liner and/or a titanium nitride (TiN) liner, among other examples.

One or more semiconductor processing tools may be used to form the interconnect layer 328 by forming one or more dielectric layers of the dielectric region 330 and forming a plurality of conductive structures 332 in the dielectric layer(s) of the dielectric region 330. For example, a deposition tool may be used to deposit a first dielectric layer of the dielectric region 330, an etch tool may be used to remove portions of the first dielectric layer to form recesses in the first dielectric layer, and a deposition tool may be used to form a first layer (e.g., a via layer, a metallization layer) of one or more conductive structures 332 in the recesses. At least a portion of the first layer of conductive structures 332 may be electrically connected and/or physically connected with the transfer gates 108 and/or with the floating diffusion nodes 110 (e.g., and/or other components of the pixel sensors 100). Similar processing operations may be performed to form additional layers of the interconnect layer 328 until a sufficient or desired arrangement of conductive structures 332 is achieved.

As further shown in FIG. 4B, the capacitors 128 and/or the capacitors 132 may be formed above the front side of the substrate layer 318 in the interconnect layer 328. In some implementations, a capacitor 128 and/or a capacitor 132 is formed by depositing a metal-insulator-metal (MIM) layer stack, and etching the MIM layer stack to define a planar capacitor structure. In some implementations, in these examples, a capacitor 128 and/or a capacitor 132 is formed by forming a trench in the dielectric region 330 and forming the MIM layer stack in the trench to define a trench capacitor structure or DTC structure. Additionally and/or alternatively, one or more of the capacitors 128 and/or one or more of the capacitors 132 may be formed in the substrate layer 318.

As shown in FIG. 4C, the bonding vias 336 may be formed on one or more conductive structures 332 in the interconnect layer 328, and bonding pads 334 may be formed above the bonding vias 336. In some implementations, one or more bonding pads 334 are formed on one or more bonding vias 336.

A deposition tool may be used to deposit the bonding pads 334 and/or the bonding vias 336 using a PVD technique, a CVD technique, an ALD technique, an electroplating technique, and/or another suitable deposition technique. In some implementations, a seed layer may be deposited, and a bonding pad 334 or a bonding via 336 may be deposited on the seed layer. In some implementations, a liner may be deposited, and a bonding pad 334 or a bonding via 336 may be deposited on the liner. The liner may include a barrier liner, a diffusion liner, and adhesion liner, and/or another type of liner. Examples of such liners may include a tantalum nitride (TaN) liner and/or a titanium nitride (TiN) liner, among other examples. In some implementations, a planarization tool may be used to perform a planarization operation (e.g., a CMP operation) to planarize a bonding pad 334 or a bonding via 336.

As indicated above, FIGS. 4A-4C are provided as an example. Other examples may differ from what is described with regard to FIGS. 4A-4C.

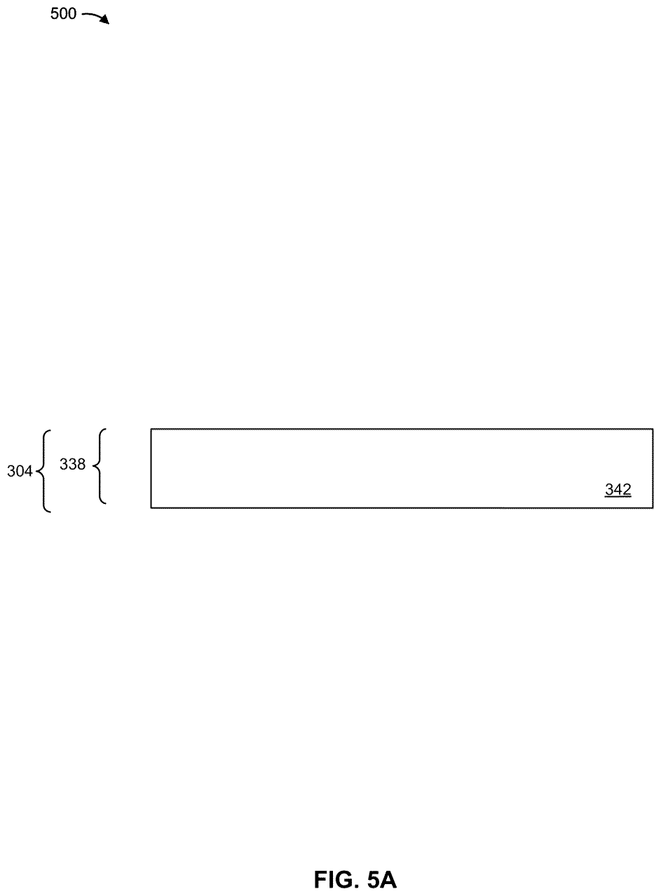

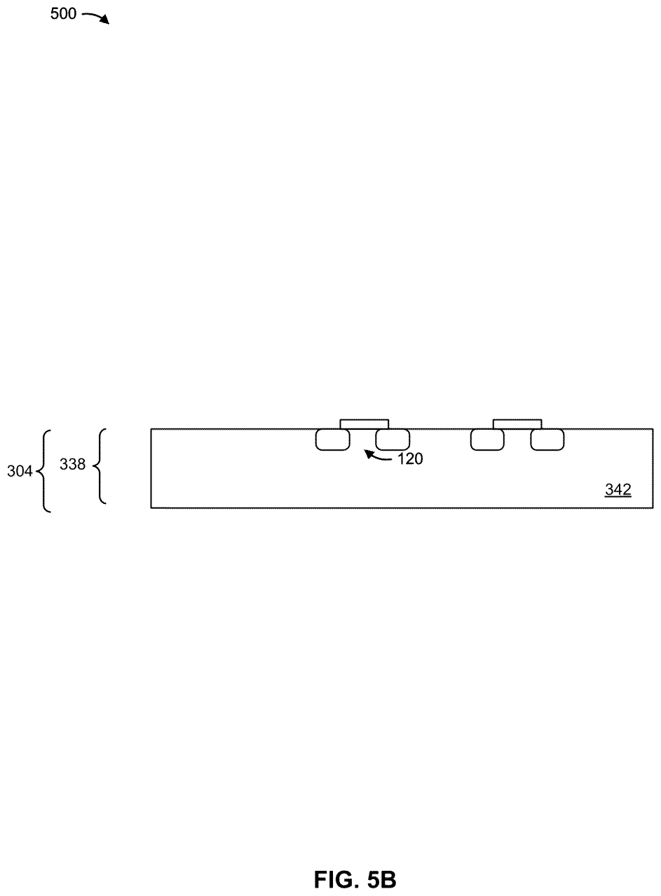

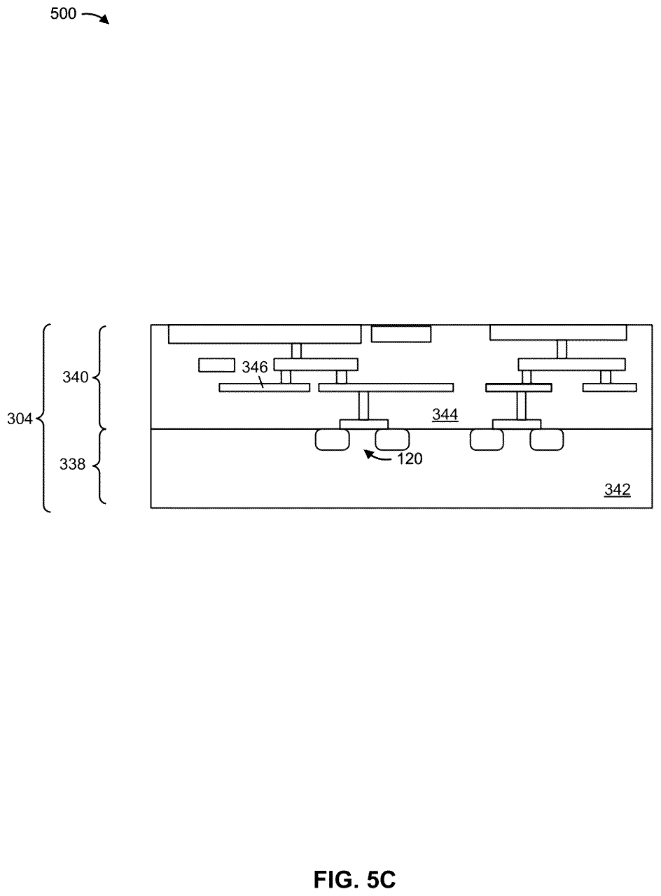

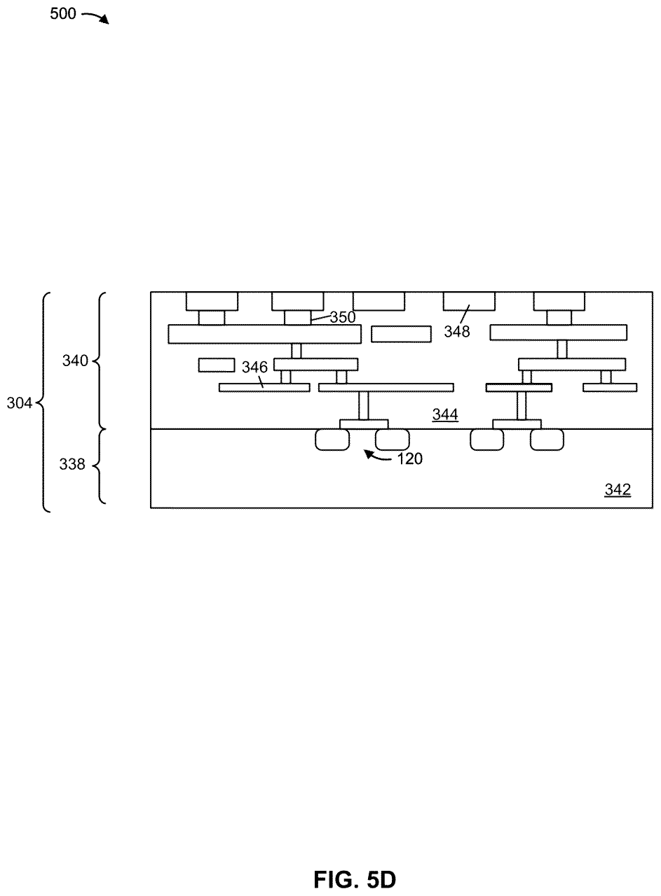

FIGS. 5A-5D are diagrams of an example implementation 500 of forming the semiconductor die 304 (or a portion thereof) described herein. In some implementations, the example implementation 500 includes an example front side process for the semiconductor die 304. In some implementations, one or more semiconductor processing tools may be used to perform one or more of the operations described in connection with the example implementation 500, such as a deposition tool, an exposure tool, a developer tool, an etch tool, a planarization tool, a plating tool, and/or another type of semiconductor processing tool.

Turning to FIG. 5A, one or more of the operations in the example implementation 500 may be performed in connection with the substrate layer 342 of the device layer 338 of the semiconductor die 304. The substrate layer 342 may be provided in the form of a semiconductor wafer (e.g., a silicon wafer), an SOI wafer, or another type of semiconductor substrate.

As shown in FIG. 5B, the integrated circuit devices of the image processing circuits 120 may be formed in and/or on the front side of the substrate layer 342 of the device layer 338. For example, a deposition tool may be used to perform various deposition operations to deposit layers of the integrated circuit devices of the image processing circuits 120, and/or to deposit photoresist layers for etching the substrate layer 342 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 342 and/or portions of the deposited layers to form the integrated circuit devices of the image processing circuits 120. As another example, a planarization tool may be used to planarize portions of the integrated circuit devices of the image processing circuits 120. As another example, an ion implantation tool may be used to implant ions in the substrate layer 342 to dopc portions of the substrate layer 342 with one or more types of dopants (e.g., p-type dopants, n-type dopants).

As shown in FIG. 5C, the interconnect layer 340 of the semiconductor die 304 may be formed above the front side of the substrate layer 342 of the semiconductor die 304. One or more semiconductor processing tools may be used to form the interconnect layer 340 by forming one or more dielectric layers of the dielectric region 344 of the interconnect layer 340 and forming a plurality of conductive structures 346 in the dielectric layer(s) of the dielectric region 344. For example, a deposition tool may be used to deposit a first dielectric layer of the dielectric region 344 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 346 in the recesses (e.g., using a CVD technique, an ALD technique, a PVD technique, an electroplating technique, and/or another type of deposition technique). At least a portion of the first layer of conductive structures 346 may be electrically connected and/or physically connected with the integrated circuit devices of the image processing circuits 120 in the substrate layer 342 (e.g., directly connected or connected through contacts). Similar processing operations may be performed to form additional layers of the interconnect layer 340 until a sufficient or desired arrangement of conductive structures 346 is achieved.

As shown in FIG. 5D, the bonding vias 350 may be formed on one or more conductive structures 346 in the interconnect layer 340, and bonding pads 348 may be formed above and/or on the bonding vias 350.

As indicated above, FIGS. 5A-5D are provided as an example. Other examples may differ from what is described with regard to FIGS. 5A-5D.

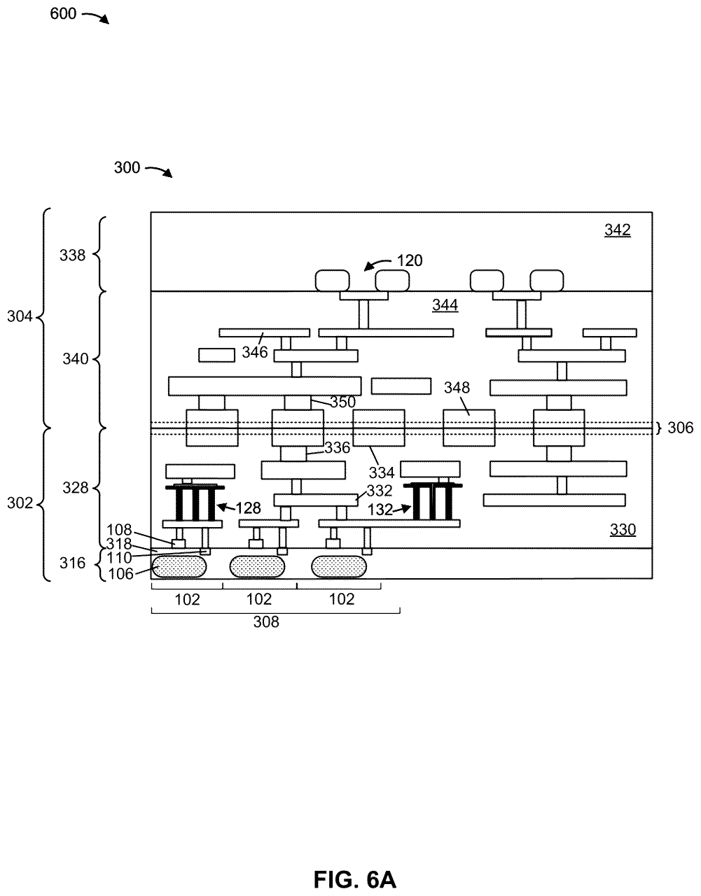

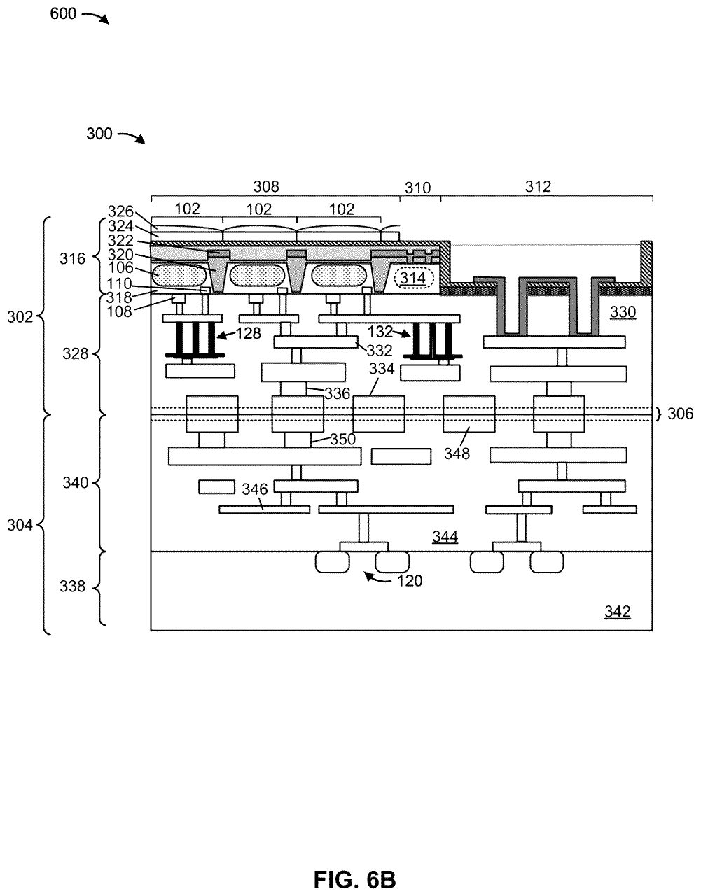

FIGS. 6A and 6B are diagrams of an example implementation 600 of forming the semiconductor device 300 (or a portion thereof) described herein. For example, the example implementation 600 may include an example of bonding the semiconductor dies 302 and 304 of the semiconductor device 300, and performing back side processing on the semiconductor die 302 after bonding. In some implementations, one or more semiconductor processing tools may be used to perform one or more of the operations described in connection with the example implementation 600, such as a deposition tool, an exposure tool, a developer tool, an etch tool, a planarization tool, a bonding tool, and/or another type of semiconductor processing tool.

As shown in FIG. 6A, a bonding operation is performed to bond the semiconductor die 302 and the semiconductor die 304 at the bonding interface 306 such that the semiconductor die 302 and the semiconductor die 304 are vertically arranged or stacked in the semiconductor device 300. The semiconductor die 302 and the semiconductor die 304 may be vertically arranged or stacked in a wafer-on-wafer configuration, a die-on-wafer configuration, a die-on-die configuration, and/or another direct bonding configuration. A bonding tool may be used to perform the bonding operation to bond the semiconductor die 302 and the semiconductor die 304 at the bonding interface 306. The bonding operation may include forming a direct bond between the semiconductor die 302 and the semiconductor die 304 through a direct physical connection of the bonding pads 334 of the semiconductor die 302 with the bonding pads 348 of the semiconductor die 304, and through a direct physical connection of the dielectric region 330 of the semiconductor die 302 with the dielectric region 344 of the semiconductor die 304. In this way, the interconnect layer 328 on the front side of the semiconductor die 302 and the interconnect layer 340 on the front side of the semiconductor die 304 are facing each other in the semiconductor device 300.

As shown in FIG. 6B, back side processing may be performed on the back side of the semiconductor die 302 after the semiconductor dies 302 and 304 are bonded at the bonding interface 306. The back side processing may include additional processing to form the pixel sensor array 308, the BLC region 310, and/or the bonding pad region 312. For example, the DTI structure 320 may be formed in the back side of the substrate layer 318 such that the DTI structure 320 laterally surrounds the photodiodes 106 of the pixel sensors 100. As another example, the metal grid structure 322 may be formed above the back side of the substrate layer 318, the color filter regions 324 may be above the photodiodes 106 on the back side of the substrate layer 318, and the micro-lenses 326 may be formed above the color filter regions 324. As another example, a metal shielding layer may be formed over the region 314 in the BLC region 310. As another example, a bonding pad structure may be formed in the bonding pad region 312.

As indicated above, FIGS. 6A and 6B are provided as an example. Other examples may differ from what is described with regard to FIGS. 6A and 6B.

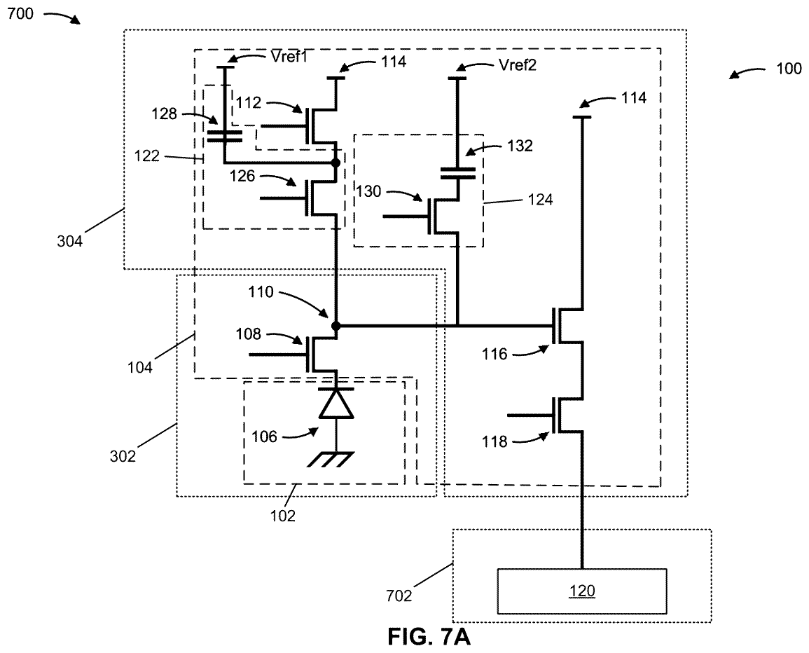

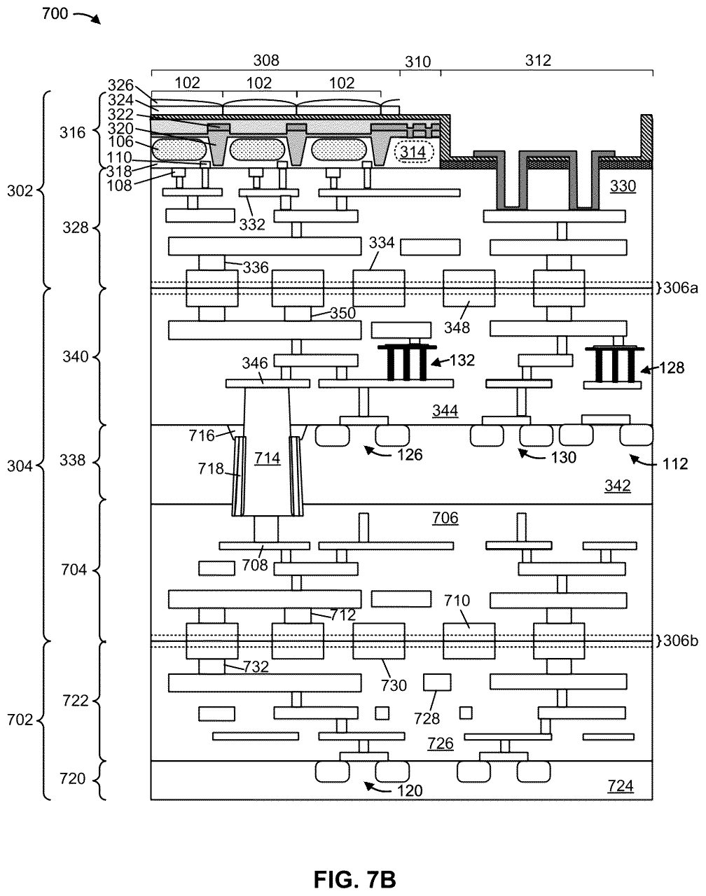

FIGS. 7A and 7B are diagrams of an example semiconductor device 700 described herein. The semiconductor device 700 includes an image sensor device such as a CMOS image sensor device that includes one or more pixel sensors 100. FIG. 7A illustrates an example distribution of components across a plurality of semiconductor dies of the semiconductor device 700. FIG. 7B illustrates a cross-sectional view of a structural implementation of the semiconductor device 700.

As shown in FIG. 7A, the sensing region 102 of a pixel sensor 100 may be included on the semiconductor die 302 (e.g., an image sensor die). Moreover, a portion of the control circuitry region 104 of the pixel sensor 100, including the transfer gate 108 and the floating diffusion node 110, may be included on the semiconductor die 302. Another portion of the control circuitry region 104 of the pixel sensor 100 may be included on the semiconductor die 304. Thus, the control circuitry region 104 of the pixel sensor is distributed across a plurality of semiconductor dies. The reset transistor 112, the source-follower gate 116, the row-select gate 118, the conversion gain circuit 122 (including the conversion gain transistor 128 and the capacitor 128), and the conversion gain circuit 124 (including the conversion gain transistor 130 and the capacitor 132) may be included on the semiconductor die 304. The semiconductor die 304 may be an application-specific integrated circuit (ASIC) die. The image processing circuit 120 may be included on a semiconductor die 702 (e.g., an ISP die).

As shown in FIG. 7B, the semiconductor dies 302, 304, and 702 may be vertically stacked or vertically arranged in the semiconductor device 700. The semiconductor die 302 and the semiconductor die 304 may be bonded at a bonding interface 306a, and the semiconductor die 304 and the semiconductor die 702 may be bonded at a bonding interface 306b. The semiconductor dies 302 and 304 may each include a similar combination and arrangement of layers and/or structures as in the semiconductor device 300. However, the capacitors 128 and the capacitors 132 are included in the semiconductor die 304 of the semiconductor device 700 instead of in the semiconductor die 302.

As further shown in FIG. 7B, the semiconductor die 304 may include another interconnect layer 704. The interconnect layer 704 may be located on a second side (e.g., a back side) of the substrate layer 342 such that the interconnect layers 340 and 704 are located on vertically opposing sides of the substrate layer 342 of the semiconductor die 304. The interconnect layer 704 may be configured to route signals and/or power between the semiconductor dies 304 and 702. The interconnect layer 704 may include a similar combination and/or arrangement of structures and/or layers as the interconnect layer 340 of the semiconductor die 304. For example, the interconnect layer 704 may include a dielectric region 706 (similar to the dielectric region 344) and a combination of conductive structures 708 (similar to the conductive structures 346) in the dielectric region 706. The interconnect layer 704 may further include bonding pads 710 and bonding vias 712. The bonding pads 710 enable the semiconductor die 304 to be bonded to the semiconductor die 702 at the bonding interface 306b, and the bonding vias 712 electrically connect one or more of the bonding pads 710 to the conductive structures 708 in the interconnect layer 704.

One or more elongated conductive structures 714 may be included in the semiconductor die 304. An elongated conductive structure 714 may extend between the interconnect layers 340 and 704 through the substrate layer 342 of the device layer 338. An elongated conductive structure 714 may include a through substrate via (TSV), a metal pillar, a metal column, and/or another type of vertically elongated conductive structure that physically connects and electrically connects with a conductive structure 346 (e.g., a metal pad) in the interconnect layer 340 at a first end, and that physically connects and electrically connects with a conductive structure 708 (e.g., a metal pad) in the interconnect layer 704. An elongated conductive structure 714 may be referred to as a TSV structure in that the elongated conductive structure 714 extends fully through the substrate layer 342 (e.g., a semiconductor substrate such as a silicon substrate) of the device layer 338, as opposed to extending fully through a dielectric layer or an insulator layer. An elongated conductive structure 714 may further extend through a shallow trench isolation (STI) region 716 that is included in the substrate layer 342 of the device layer 338.

An elongated conductive structure 714 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. An STI region 716 may include one or more dielectric materials such as a silicon oxide material (SiOₓ such as SiO₂), a silicon nitride material (SiₓN_{y} such Si₃N₄), and/or another suitable dielectric material.

One or more liners 718 may be included between the sidewalls of the elongated conductive structure 714 and the substrate layer 342. The one or more liners 718 may include adhesion liners, barrier liners, diffusion liners, and/or another type of liners. In some implementations, a liner 718 includes a high-k dielectric liner that includes a high-k dielectric material having a dielectric constant that is greater than approximately 3.9. Examples of such materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, a liner 718 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 7B, the capacitors 128 and/or the capacitors 132 may be included in the interconnect layer 340 of the semiconductor die 304. In other words, the capacitors 128 and/or the capacitors 132 may be included on the front side of the semiconductor die 304. The reset transistor 112, the source-follower gate 116, the row-select gate 118, the conversion gain transistor 126, and/or the conversion gain transistor 130 may be included in and/or on the substrate layer 342 of the semiconductor die 304. In some implementations, the reset transistor 112, the source-follower gate 116, the row-select gate 118, the conversion gain transistor 126, and/or the conversion gain transistor 130 may be included in and/or on a front side of the substrate layer 342 facing the interconnect layer 340. In some implementations, the reset transistor 112, the source-follower gate 116, the row-select gate 118, the conversion gain transistor 126, and/or the conversion gain transistor 130 may be included in and/or on a back side of the substrate layer 342 facing the interconnect layer 704.

The semiconductor die 702 may include a device layer 720 and an interconnect layer 722 vertically adjacent to the device layer 720. The device layer 720 may include a substrate layer 724. The substrate layer 724 may include a silicon (Si) substrate and/or another type of semiconductor substrate. The integrated circuit devices of the image processing circuits 120 may be included in and/or on the substrate layer 724. The image processing circuits 120 of the semiconductor die 702 may be configured to perform functions such as compression, storage, file management, and/or other functions associated with images and/or video generated by the semiconductor device 700. The integrated circuit devices of the image processing circuits 120 may include transistors, capacitors, resistors, and/or other integrated circuit devices.

The interconnect layer 704 may be located vertically adjacent to the front side of the substrate layer 724. The interconnect layer 722 may include a similar combination and/or arrangement of structures and/or layers as the interconnect layer 704 of the semiconductor die 304. For example, the interconnect layer 722 may include a dielectric region 726 (similar to the dielectric region 706) and a combination of conductive structures 728 (similar to the conductive structures 708) in the dielectric region 726. Moreover, the interconnect layer 722 may include bonding pads 730 that are electrically coupled to one or more of the conductive structures 728 through bonding vias 732. These layers and/or structures may have a reversed vertical arrangement relative to the interconnect layer 704, which enables the semiconductor die 304 and the semiconductor die 702 to be bonded at the bonding interface 306b such that the interconnect layer 704 and the interconnect layer 722 are facing each other and bonded together.

At the bonding interface 306b, the bonding pads 710 of the semiconductor die 304 and bonding pads 730 of the semiconductor die 702 are directly bonded by metal-to-metal bonds. Moreover, the dielectric region 706 of the semiconductor die 304 and the dielectric region 726 of the semiconductor die 702 are directly bonded by dielectric-to-dielectric bonds.

As indicated above, FIGS. 7A and 7B are provided as an example. Other examples may differ from what is described with regard to FIGS. 7A and 7B.

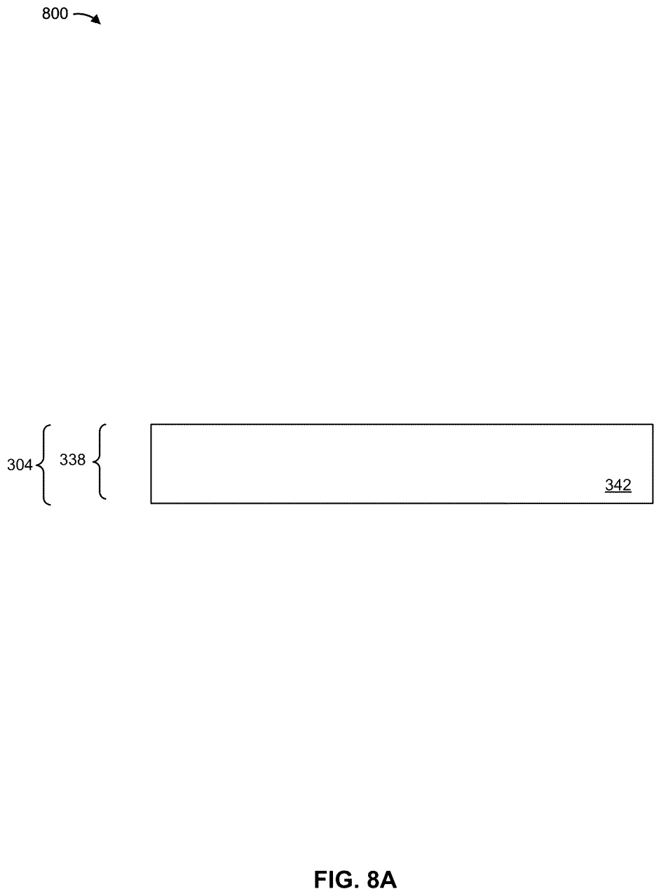

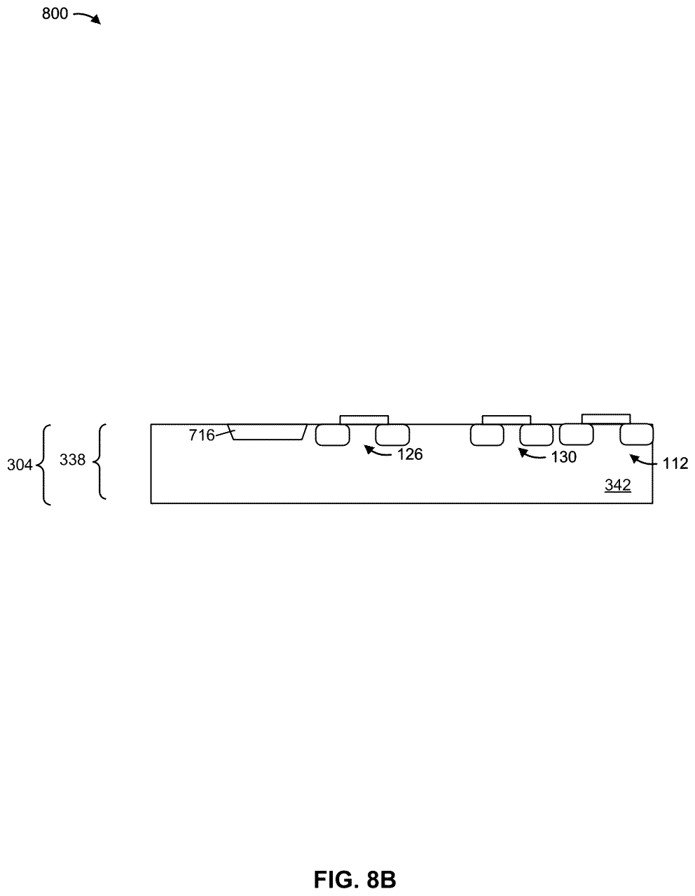

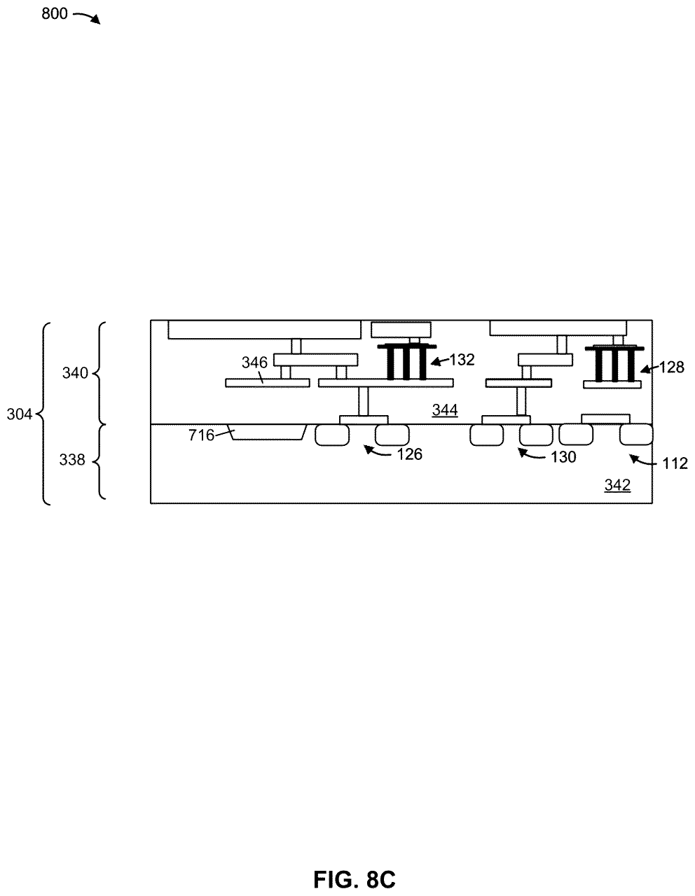

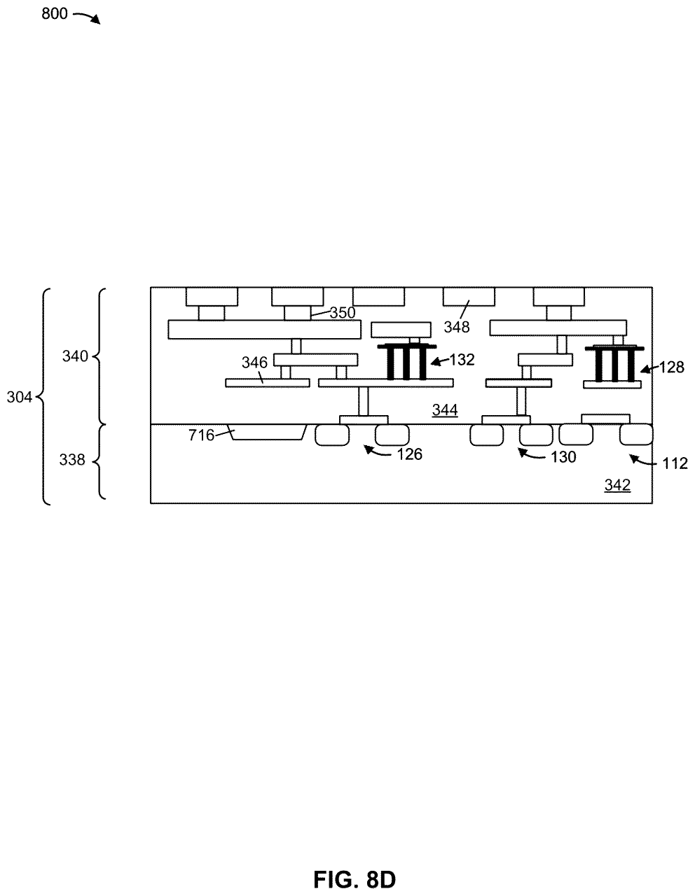

FIGS. 8A-8D are diagrams of an example implementation 800 of forming the semiconductor die 304 (or a portion thereof) of the semiconductor device 700 described herein. In some implementations, the example implementation 800 includes an example front side process for the semiconductor die 304. In some implementations, one or more semiconductor processing tools may be used to perform one or more of the operations described in connection with the example implementation 800, such as a deposition tool, an exposure tool, a developer tool, an etch tool, a planarization tool, a plating tool, and/or another type of semiconductor processing tool.

Turning to FIG. 8A, one or more of the operations in the example implementation 800 may be performed in connection with the substrate layer 342 of the device layer 338 of the semiconductor die 304. The substrate layer 342 may be provided in the form of a semiconductor wafer (e.g., a silicon wafer), an SOI wafer, or another type of semiconductor substrate.

As shown in FIG. 8B, the integrated circuit devices may be formed in and/or on the front side of the substrate layer 342 of the semiconductor die 304. For example, one or more of the reset transistor 112, the source-follower gate 116 (not shown), the row-select gate 118 (not shown), the conversion gain transistor 126, the capacitor 128 (not shown), the conversion gain transistor 130, and/or the capacitor 132 (not shown) may be formed in and/or on the front side of the substrate layer 342.

One or more semiconductor processing tools may be used to form one or more portions of the integrated circuit devices. For example, a deposition tool may be used to perform various deposition operations to deposit layers of the integrated circuit devices, and/or to deposit photoresist layers for etching the substrate layer 342 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 342 and/or portions of the deposited layers to form the integrated circuit devices. As another example, a planarization tool may be used to planarize portions of the integrated circuit devices. As another example, an ion implantation tool may be used to implant ions in the substrate layer 342 to dope portions of the substrate layer 342 with one or more types of dopants (e.g., p-type dopants, n-type dopants).

As further shown in FIG. 8B, an STI region 716 may be formed in the front side of the substrate layer 342. The STI region 716 may be formed in a recess in the substrate layer 342. In some implementations, a pattern in a photoresist layer is used to etch the substrate layer 342 to form the recess in the substrate layer 342. In these implementations, a deposition tool may be used to form the photoresist layer on the substrate layer 342. An exposure tool may be used to expose the photoresist layer to a radiation source to pattern the photoresist layer. A developer tool may be used to develop and remove portions of the photoresist layer to expose the pattern. An etch tool may be used to etch the substrate layer 342 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 342 based on a pattern.

A deposition tool may be used to deposit the dielectric material of the STI region 716 in the recess using a CVD technique, an ALD technique, a PVD technique, an oxidation technique, and/or another suitable deposition technique. The dielectric material of the STI region 716 may be deposited in one or more deposition operations. In some implementations, a planarization tool may be used to perform a planarization operation (e.g., a CMP operation) to planarize the STI region 716 after the dielectric material of the STI region 716 is deposited.

As shown in FIG. 8C, the interconnect layer 340 of the semiconductor die 304 may be formed above the front side of the substrate layer 342 of the semiconductor die 304. One or more semiconductor processing tools may be used to form the interconnect layer 340 by forming one or more dielectric layers of the dielectric region 344 of the interconnect layer 340 and forming a plurality of conductive structures 346 in the dielectric layer(s) of the dielectric region 344. For example, a deposition tool may be used to deposit a first dielectric layer of the dielectric region 344 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 346 in the recesses (e.g., using a CVD technique, an ALD technique, a PVD technique, an electroplating technique, and/or another type of deposition technique). At least a portion of the first layer of conductive structures 346 may be electrically connected and/or physically connected with the integrated circuit devices in the substrate layer 342 (e.g., directly connected or connected through contacts). Similar processing operations may be performed to form additional layers of the interconnect layer 340 until a sufficient or desired arrangement of conductive structures 346 is achieved.

As further shown in FIG. 8C, one or more capacitor structures, such as one or more capacitors 128 and/or one or more capacitors 132, may be formed above the front side of the substrate layer 342 in the interconnect layer 340. In some implementations, a capacitor 128 and/or a capacitor 132 is formed by depositing a metal-insulator-metal (MIM) layer stack, and etching the MIM layer stack to define a planar capacitor structure. In some implementations, in these examples, a capacitor 128 and/or a capacitor 132 is formed by forming a trench in the dielectric region 344 and forming the MIM layer stack in the trench to define a trench capacitor structure or DTC structure. Additionally and/or alternatively, one or more of the capacitors 128 and/or one or more of the capacitors 132 may be formed in the substrate layer 342.

As shown in FIG. 8D, the bonding vias 350 may be formed on one or more conductive structures 346 in the interconnect layer 340, and bonding pads 348 may be formed above and/or on the bonding vias 350.

As indicated above, FIGS. 8A-8D are provided as an example. Other examples may differ from what is described with regard to FIGS. 8A-8D.

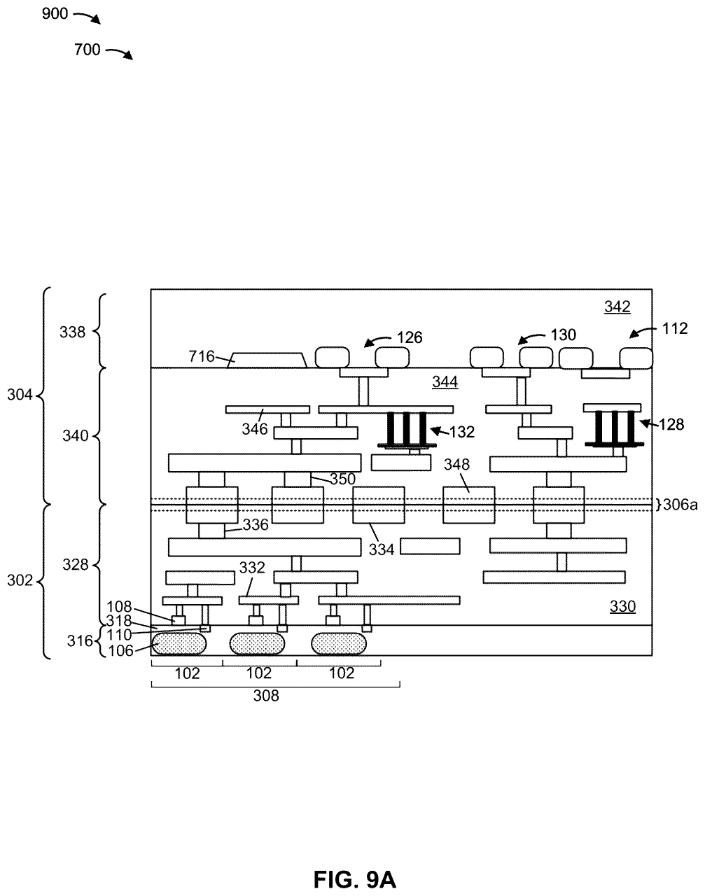

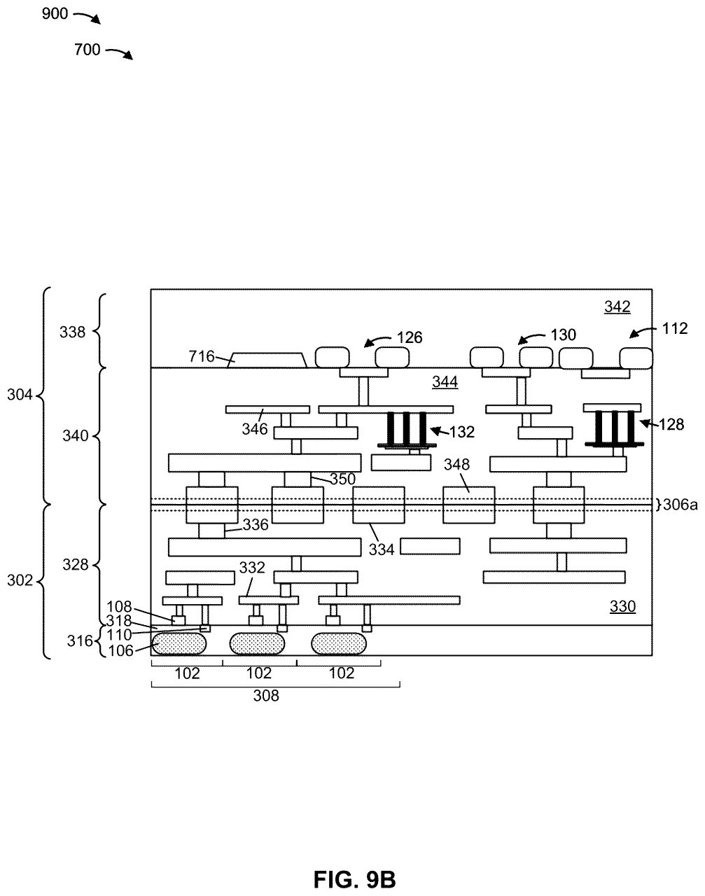

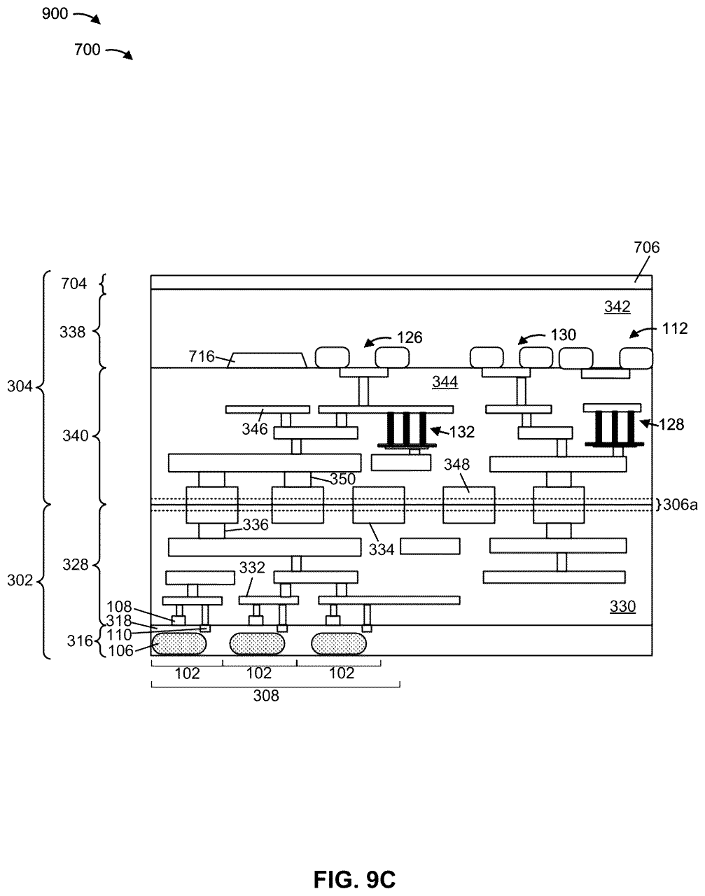

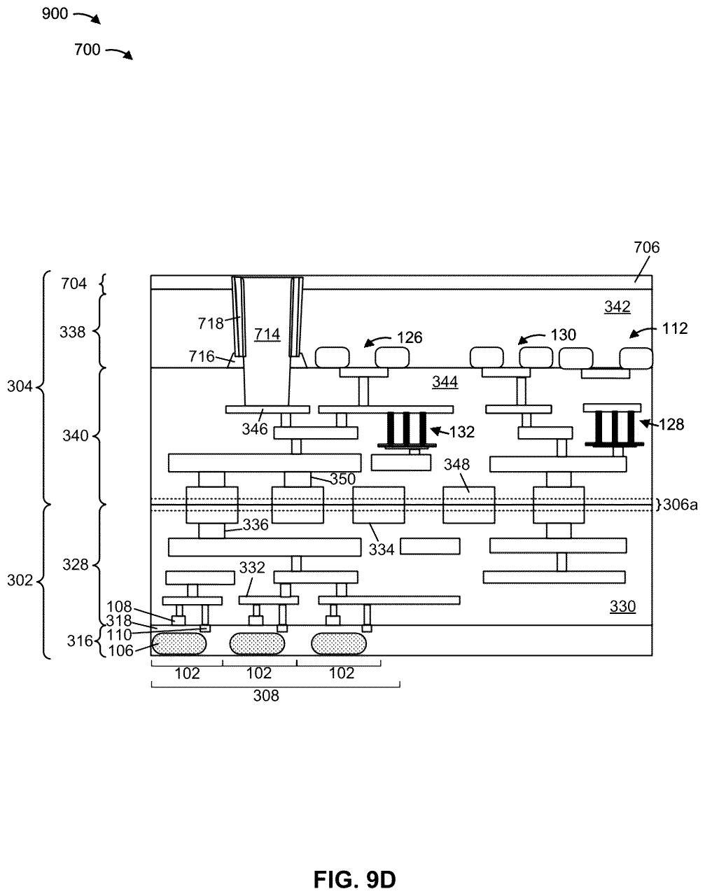

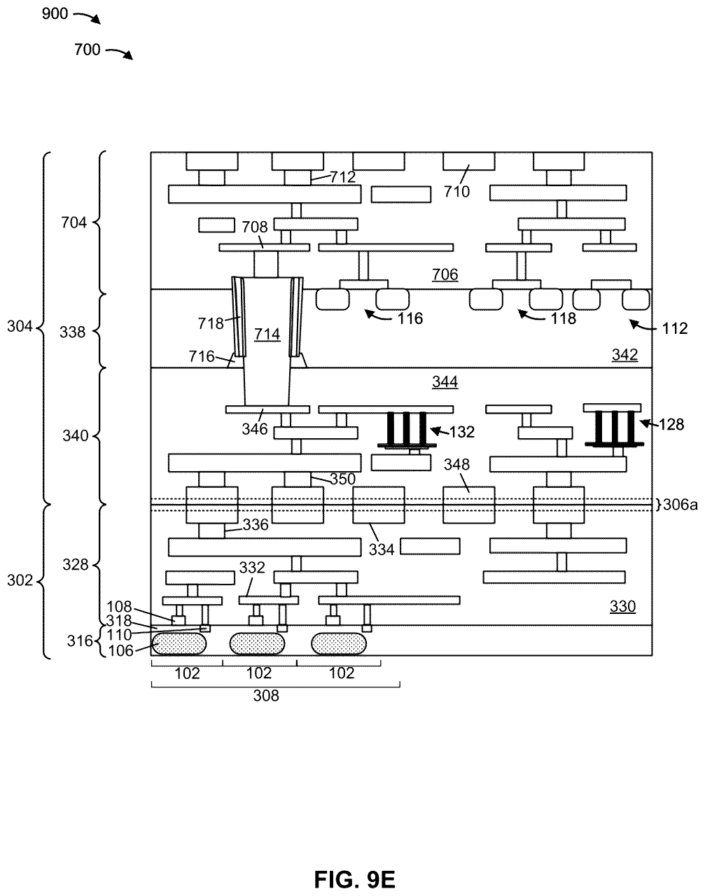

FIGS. 9A-9E are diagrams of an example implementation 900 of forming the semiconductor device 700 (or a portion thereof) described herein. For example, the example implementation 900 may include an example of bonding the semiconductor dies 302 and 304 of the semiconductor device 700, and performing back side processing on the semiconductor die 304 after bonding. In some implementations, one or more semiconductor processing tools may be used to perform one or more of the operations described in connection with the example implementation 900, such as a deposition tool, an exposure tool, a developer tool, an etch tool, a planarization tool, a bonding tool, and/or another type of semiconductor processing tool.

As shown in FIG. 9A, a bonding operation is performed to bond the semiconductor die 302 and the semiconductor die 304 at the bonding interface 306a such that the semiconductor die 302 and the semiconductor die 304 are vertically arranged or stacked in the semiconductor device 700. The bonding operation may include similar bonding techniques as described in connection with FIG. 6A.

As shown in FIG. 9B, the semiconductor device 700 may be flipped so that back side processing may be performed on the back side of the semiconductor die 304 after the semiconductor dies 302 and 304 are bonded at the bonding interface 306a. While not shown in FIG. 9B, back side processing may include forming one or more integrated circuit devices in and/or on the back side of the substrate layer 342 of the semiconductor die 304. For example, one or more of the reset transistor 112, the source-follower gate 116 (not shown), the row-select gate 118 (not shown), the conversion gain transistor 126, the capacitor 128 (not shown), the conversion gain transistor 130, and/or the capacitor 132 (not shown) may be formed in and/or on the back side of the substrate layer 342.

As shown in FIG. 9C, a portion of the dielectric region 706 of the interconnect layer 704 may be formed over the back side of the substrate layer 342 of the semiconductor die 304.

As shown in FIG. 9D, one or more elongated conductive structures 714 (e.g., one or more TSVs) may be formed through the substrate layer 342 of the semiconductor die 304 such that the one or more elongated conductive structures 714 land on one or more conductive structures 346 in the interconnect layer 340 on the front side of the semiconductor die 304.

To form an elongated conductive structure 714, a recess may be formed through the dielectric region 706, through the substrate layer 342 from the back side of the substrate layer 342, and into the dielectric region 344 of the interconnect layer 340. The recess may extend through the STI region 716 in the substrate layer 342, and into the dielectric region 344 in the interconnect layer 340. A conductive structure 346 in the interconnect layer 340 may be exposed through the recess.

In some implementations, a pattern in a photoresist layer is used to etch the dielectric region 706, the substrate layer 342, the STI region 716, and/or the dielectric region 344 to form the recess. In these implementations, a deposition tool may be used to form the photoresist layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the dielectric region 706, through the substrate layer 342, through the STI region 716, and/or into the dielectric region 344 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the material of the elongated conductive structure 714 in the recess using a CVD technique, a PVD technique, an ALD technique, an electroplating technique, and/or another suitable deposition technique. The elongated conductive structure 714 may be deposited in one or more deposition operations. In some implementations, a seed layer is first deposited, and the elongated conductive structure 714 is deposited on the seed layer. In some implementations, one or more liners 718 (e.g., adhesion liners, barrier liners, diffusion liners) are deposited in the recess, and then the elongated conductive structure 714 is deposited on the liners(s) 718. In some implementations, a planarization tool is used to perform a planarization operation (e.g., a CMP operation) to planarize the elongated conductive structure 714 after the elongated conductive structure 714 is deposited.

As shown in FIG. 9E, additional portions of the interconnect layer 704 may be formed above the back side of the substrate layer 342. One or more semiconductor processing tools may be used to form the interconnect layer 704 by forming one or more dielectric layers of the dielectric region 706 of the interconnect layer 704 and forming a plurality of conductive structures 708 in the dielectric layer(s) of the dielectric region 706. For example, a deposition tool may be used to deposit a first dielectric layer of the dielectric region 706 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 708 in the recesses (e.g., using a CVD technique, an ALD technique, a PVD technique, an electroplating technique, and/or another type of deposition technique). At least a portion of the first layer of conductive structures 708 may be electrically connected and/or physically connected with the elongated conductive structure 714. Similar processing operations may be performed to form additional layers of the interconnect layer 704 until a sufficient or desired arrangement of conductive structures 708 is achieved.

As shown in FIG. 9E, the bonding vias 712 may be formed on one or more conductive structures 708 in the interconnect layer 704, and bonding pads 710 may be formed above and/or on the bonding vias 712.

As indicated above, FIGS. 9A-9E are provided as an example. Other examples may differ from what is described with regard to FIGS. 9A-9E.

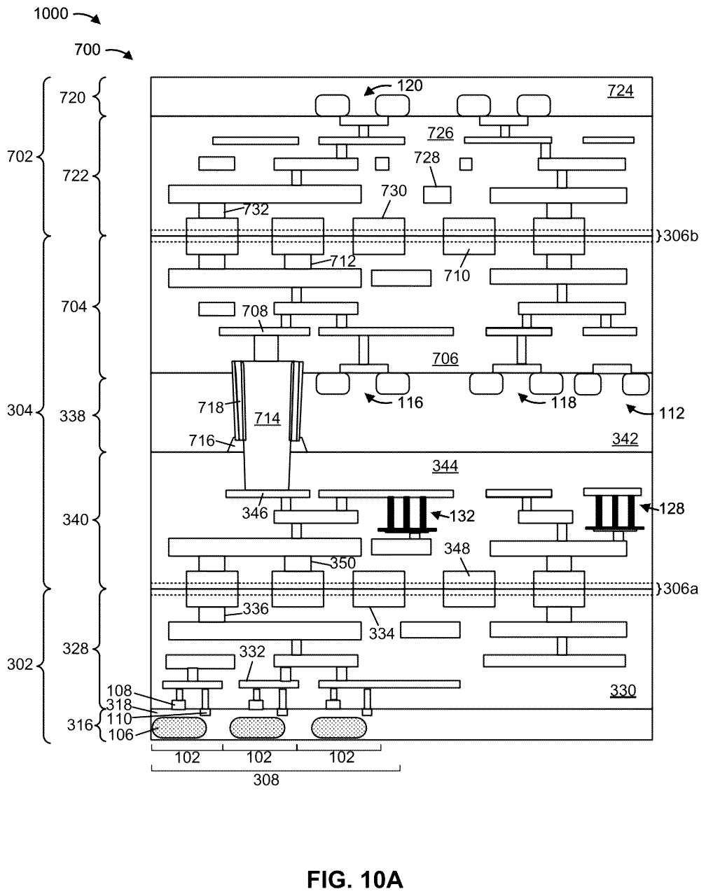

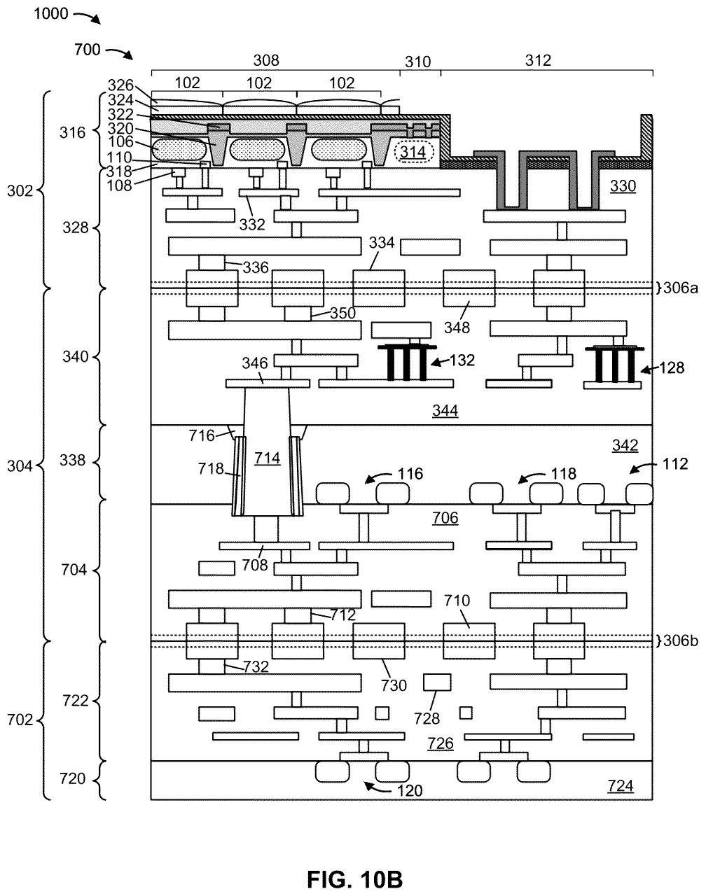

FIGS. 10A and 10B are diagrams of an example implementation 1000 of forming the semiconductor device 700 (or a portion thereof) described herein. For example, the example implementation 1000 may include an example of bonding the semiconductor dies 304 and 702 of the semiconductor device 700, and performing back side processing on the semiconductor die 302 after bonding. In some implementations, one or more semiconductor processing tools may be used to perform one or more of the operations described in connection with the example implementation 1000, such as a deposition tool, an exposure tool, a developer tool, an etch tool, a planarization tool, a bonding tool, and/or another type of semiconductor processing tool.

As shown in FIG. 10A, a bonding operation is performed to bond the semiconductor die 304 and the semiconductor die 702 at the bonding interface 306b such that the semiconductor die 304 and the semiconductor die 702 are vertically arranged or stacked in the semiconductor device 700. The semiconductor die 304 and the semiconductor die 702 may be vertically arranged or stacked in a wafer-on-wafer configuration, a die-on-wafer configuration, a die-on-die configuration, and/or another direct bonding configuration. A bonding tool may be used to perform the bonding operation to bond the semiconductor die 304 and the semiconductor die 702 at the bonding interface 306b. The bonding operation may include forming a direct bond between the semiconductor die 304 and the semiconductor die 702 through a direct physical connection of the bonding pads 710 of the semiconductor die 304 with the bonding pads 730 of the semiconductor die 702, and through a direct physical connection of the dielectric region 706 of the semiconductor die 304 with the dielectric region 726 of the semiconductor die 702. In this way, the interconnect layer 704 on the back side of the semiconductor die 304 and the interconnect layer 722 on the front side of the semiconductor die 702 are facing each other in the semiconductor device 700.

The semiconductor die 702 may be formed by similar operations and/or using similar techniques as described in connection with FIGS. 5A-5D for the semiconductor die 304 and/or similar operations and/or using similar techniques as described in connection with FIGS. 8A-8D for the semiconductor die 304.

As shown in FIG. 10B, back side processing may be performed on the back side of the semiconductor die 304 after the semiconductor dies 304 and 702 are bonded at the bonding interface 306b. The back side processing may include additional processing described in connection with FIG. 6B to form the pixel sensor array 308, the BLC region 310, and/or the bonding pad region 312. For example, the DTI structure 320 may be formed in the back side of the substrate layer 318 such that the DTI structure 320 laterally surrounds the photodiodes 106 of the pixel sensors 100. As another example, the metal grid structure 322 may be formed above the back side of the substrate layer 318, the color filter regions 324 may be above the photodiodes 106 on the back side of the substrate layer 318, and the micro-lenses 326 may be formed above the color filter regions 324. As another example, a metal shielding layer may be formed over the region 314 in the BLC region 310. As another example, a bonding pad structure may be formed in the bonding pad region 312.

As indicated above, FIGS. 10A and 10B are provided as an example. Other examples may differ from what is described with regard to FIGS. 10A and 10B.

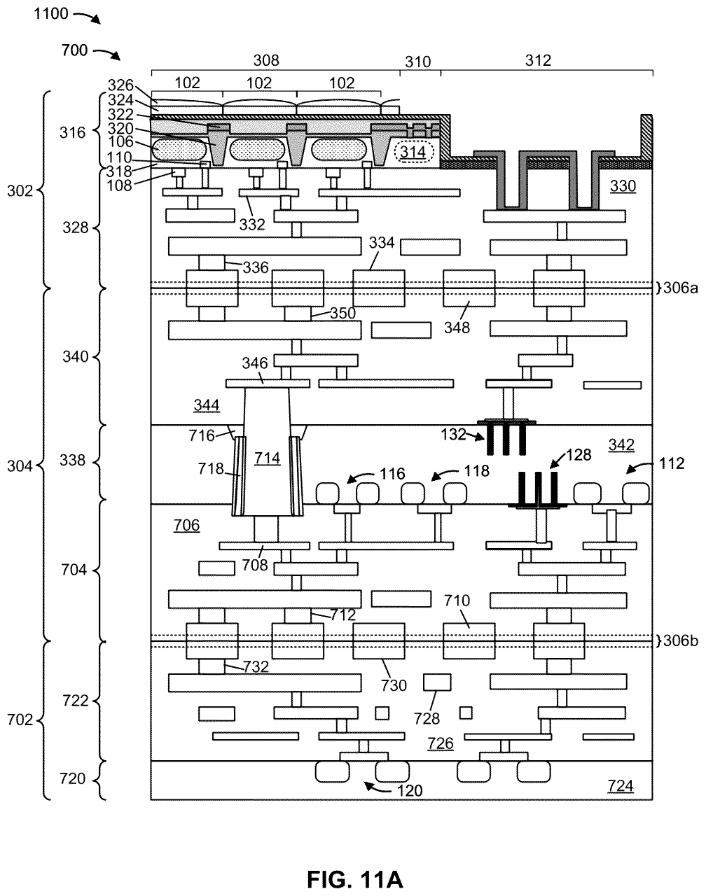

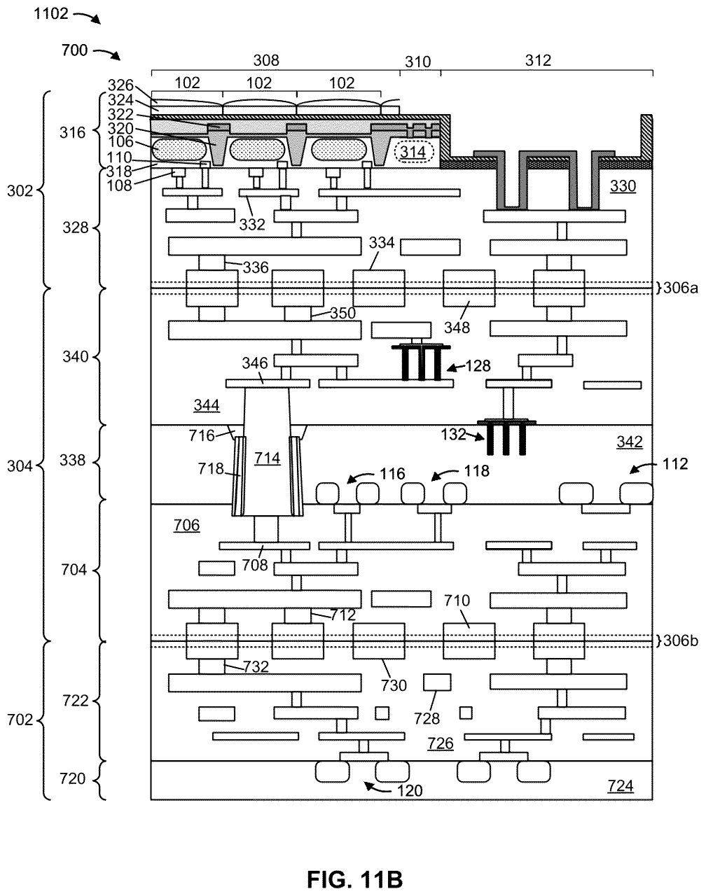

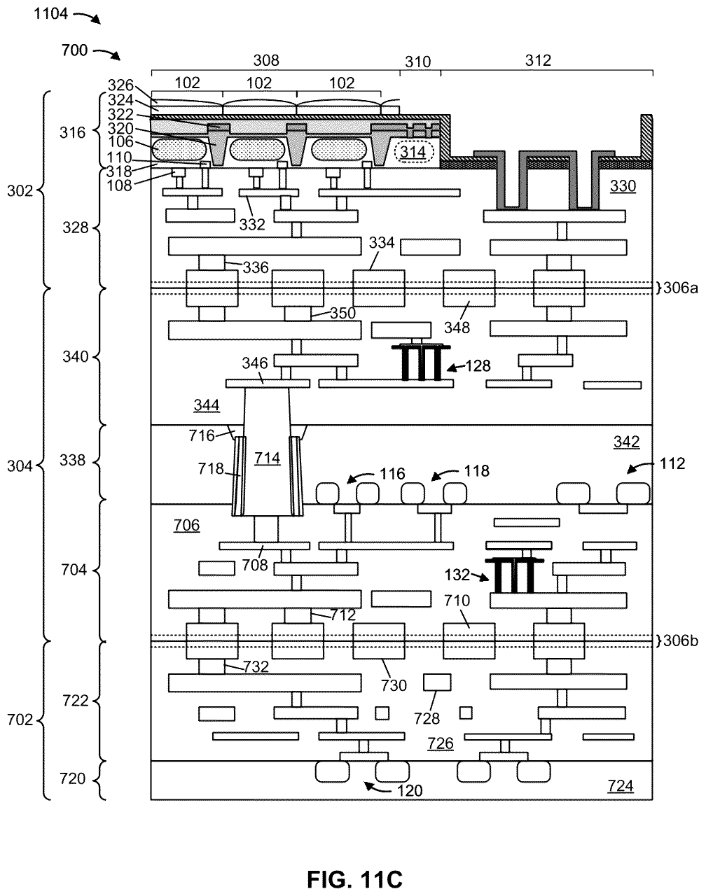

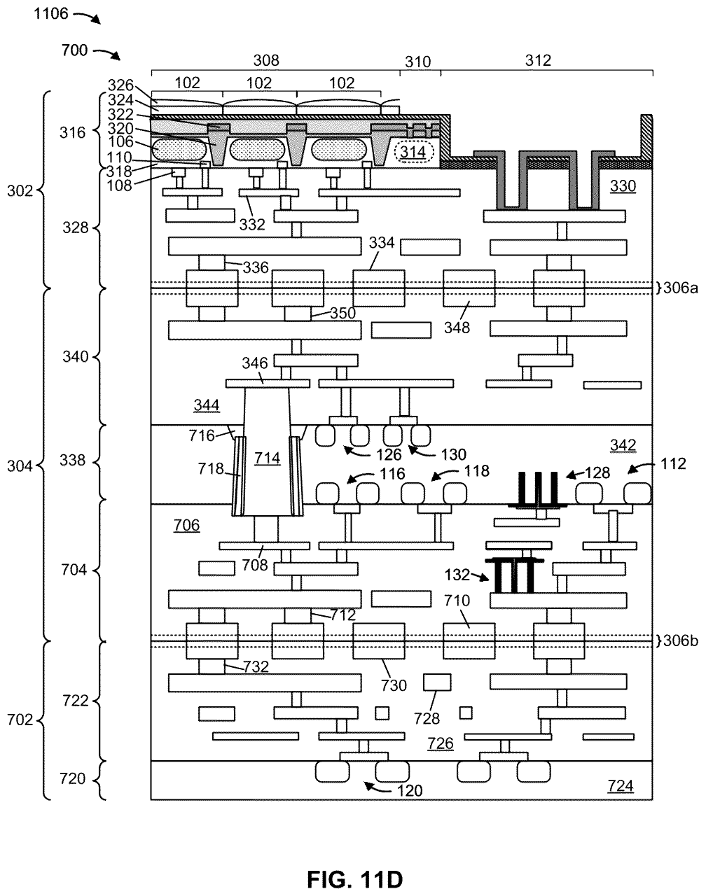

FIGS. 11A-11D are diagrams of example implementations of the semiconductor device 700 described herein. The example implementations illustrated in FIGS. 11A-11D include alternative structural arrangements to the example implementation illustrated in FIG. 7B.

FIG. 11A illustrates an example implementation 1100 of the semiconductor device 700 in which the capacitors 128 and/or the capacitors 132 of the pixel sensors 100 are included in the substrate layer 342 of the semiconductor die 304. In some implementations, one or more capacitors 128 and/or one or more capacitors 132 may be included in and/or on the front side of the substrate layer 342 facing the interconnect layer 340. In some implementations, one or more capacitors 128 and/or one or more capacitors 132 may be included in and/or on the back side of the substrate layer 342 facing the interconnect layer 704.

FIG. 11B illustrates an example implementation 1102 of the semiconductor device 700 in which one or more capacitors 128 and/or one or more capacitors 132 of the pixel sensors 100 are included in and/or on the front side substrate layer 342 of the semiconductor die 304, and one or more capacitors 128 and/or one or more capacitors 132 are included in the interconnect layer 340 of the semiconductor die 304 (e.g., the front side interconnect layer).

FIG. 11C illustrates an example implementation 1104 of the semiconductor device 700 in which one or more capacitors 128 and/or one or more capacitors 132 of the pixel sensors 100 are included in the interconnect layer 340 of the semiconductor die 304 (e.g., the front side interconnect layer), and one or more capacitors 128 and/or one or more capacitors 132 are included in the interconnect layer 704 (e.g., the back side interconnect layer).

FIG. 11D illustrates an example implementation 1106 of the semiconductor device 700 in which one or more capacitors 128 and/or one or more capacitors 132 of the pixel sensors 100 are included in and/or on the back side substrate layer 342 of the semiconductor die 304, and one or more capacitors 128 and/or one or more capacitors 132 are included in the interconnect layer 704 of the semiconductor die 304 (e.g., the back side interconnect layer).

As indicated above, FIGS. 11A-11D are provided as an example. Other examples may differ from what is described with regard to FIGS. 11A-11D.

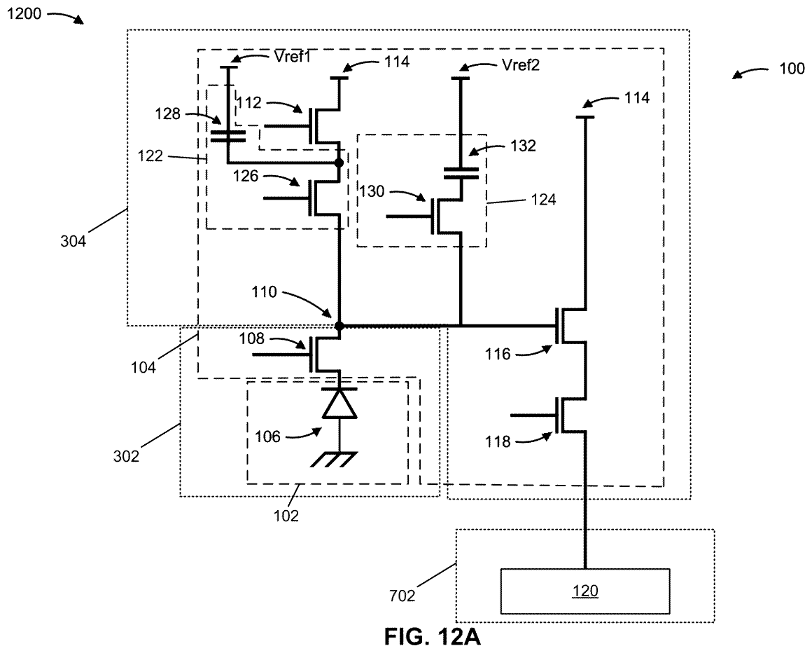

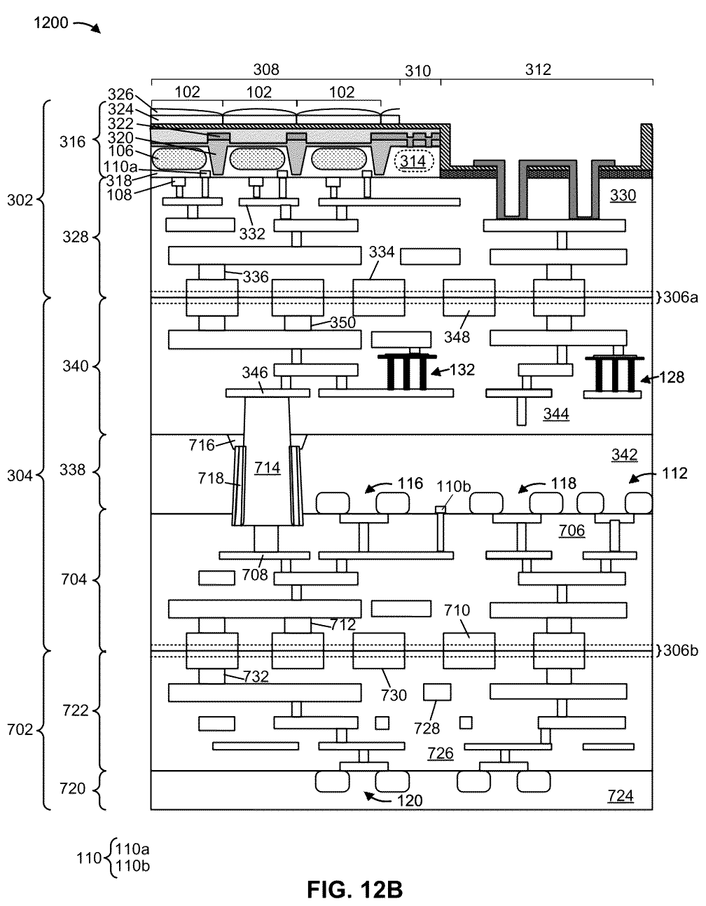

FIGS. 12A and 12B are diagrams of an example semiconductor device 1200 described herein. The semiconductor device 1200 includes an image sensor device such as a CMOS image sensor device that includes one or more pixel sensors 100. FIG. 12A illustrates an example distribution of components across a plurality of semiconductor dies of the semiconductor device 1200. FIG. 12B illustrates a cross-sectional view of a structural implementation of the semiconductor device 1200.

As shown in FIG. 12A, the sensing region 102 of a pixel sensor 100 may be included on the semiconductor die 302 (e.g., an image sensor die). Moreover, the transfer gate 108 of the control circuitry region 104 of the pixel sensor 100 may be included on the semiconductor die 302.

The floating diffusion node 110 of the control circuitry region 104 of the pixel sensor 100 is distributed across the semiconductor dies 302 and 304. A portion of the floating diffusion node 110 is included on the semiconductor die 302, and another portion of the control circuitry region 104 of the pixel sensor 100 may be included on the semiconductor die 304. The portion of the floating diffusion node 110 on the semiconductor die 304 may provide an auxiliary charge storage area for the pixel sensor 100, which may further increase the FWC of the pixel sensor 100.

The reset transistor 112, the source-follower gate 116, the row-select gate 118, the conversion gain circuit 122 (including the conversion gain transistor 128 and the capacitor 128), and the conversion gain circuit 124 (including the conversion gain transistor 130 and the capacitor 132) may also be included on the semiconductor die 304. The image processing circuit 120 may be included on a semiconductor die 702.

As shown in FIG. 12B, the semiconductor dies 302, 304, and 702 of the semiconductor device 1200 may include a similar combination and arrangement of layers and/or structures as the semiconductor device 700. However, as indicated above in FIG. 12A, the floating diffusion nodes 110 of the pixel sensors 100 may be distributed across the semiconductor dies 302 and 304. For example, portions 110a of the floating diffusion nodes 110 may be included in the substrate layer 318 of the semiconductor die 302. As another example, portions 110b of the floating diffusion nodes 110 may be included in the substrate layer 342 of the semiconductor die 304. In some implementations, the portions 110b of the floating diffusion nodes 110 may be included in the front side of the substrate layer 342 of the semiconductor die 304. In some implementations, the portions 110b of the floating diffusion nodes 110 may be included in the back side of the substrate layer 342 of the semiconductor die 304.

As indicated above, FIGS. 12A and 12B are provided as an example. Other examples may differ from what is described with regard to FIGS. 12A and 12B.

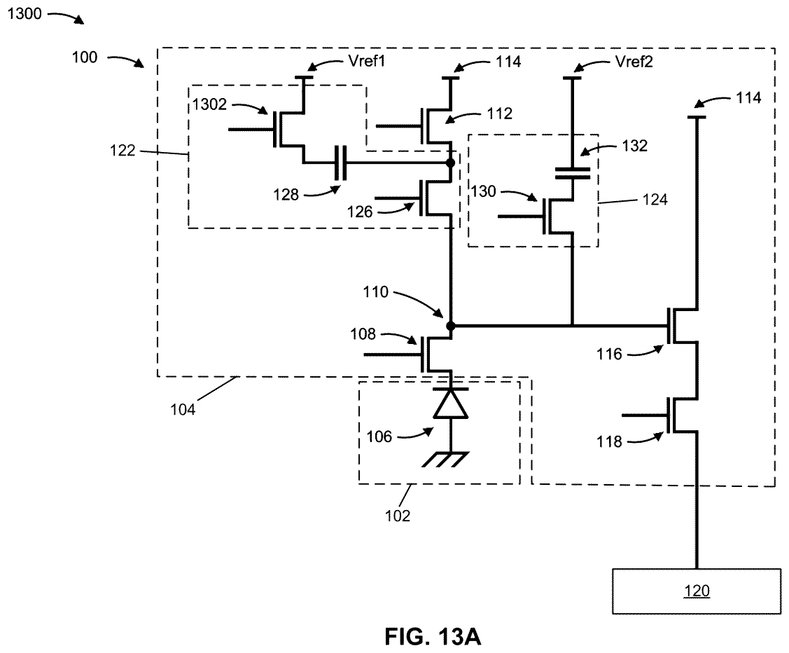

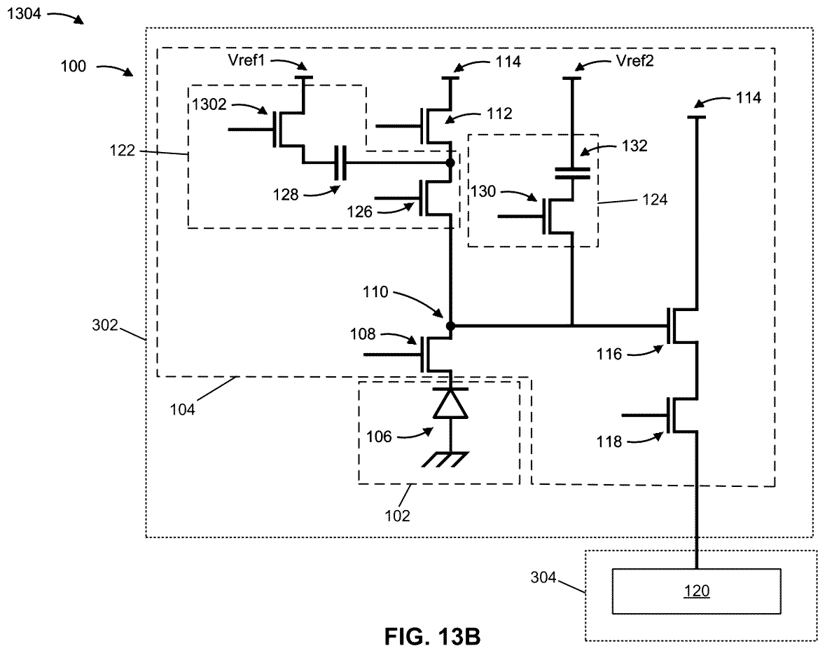

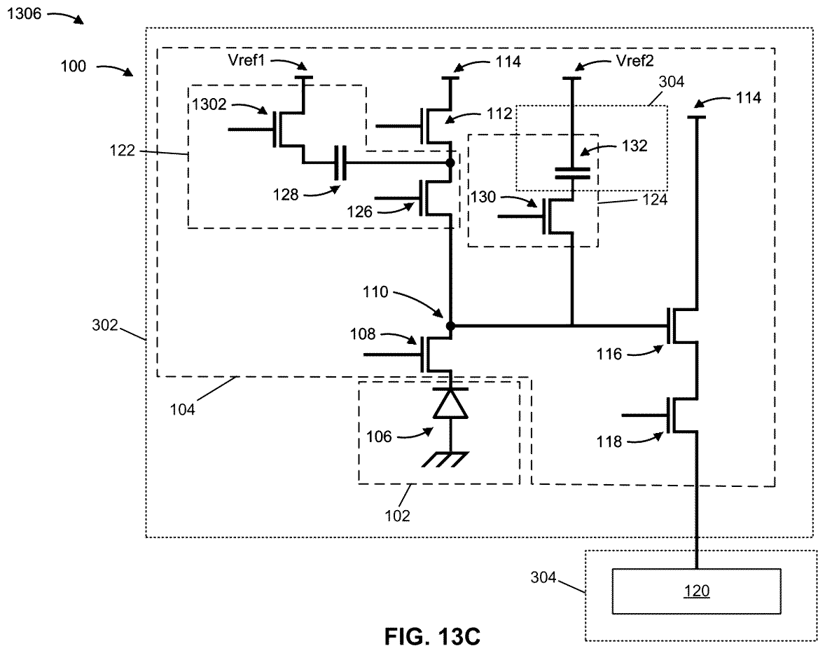

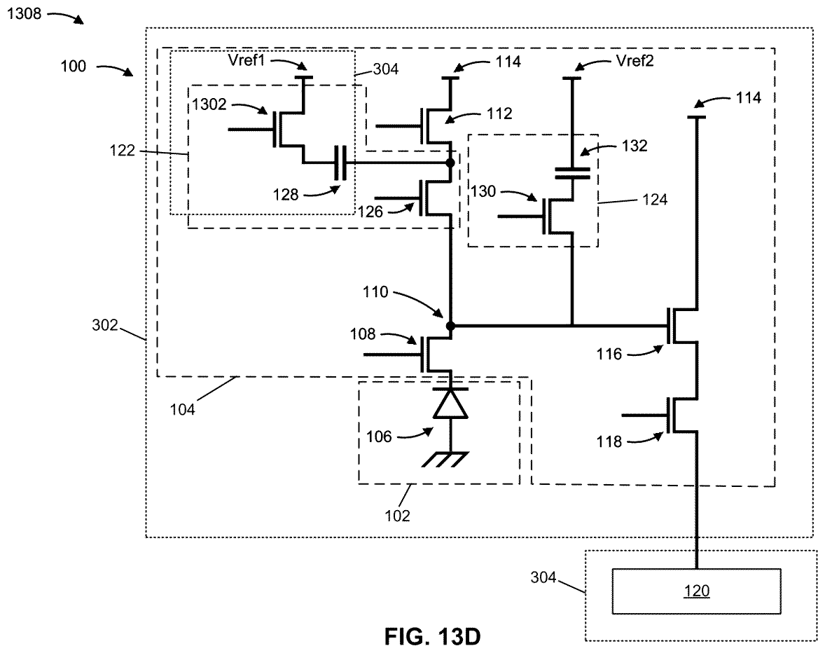

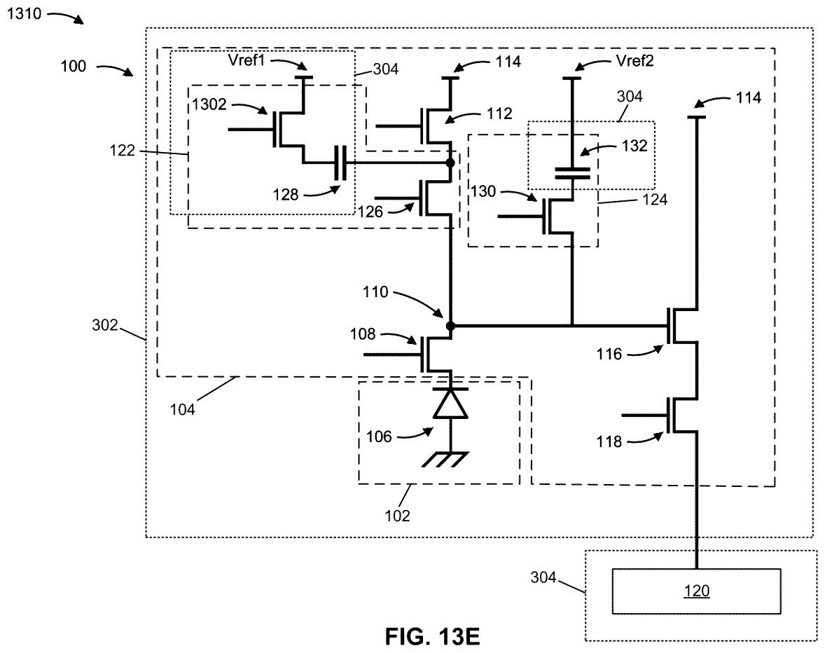

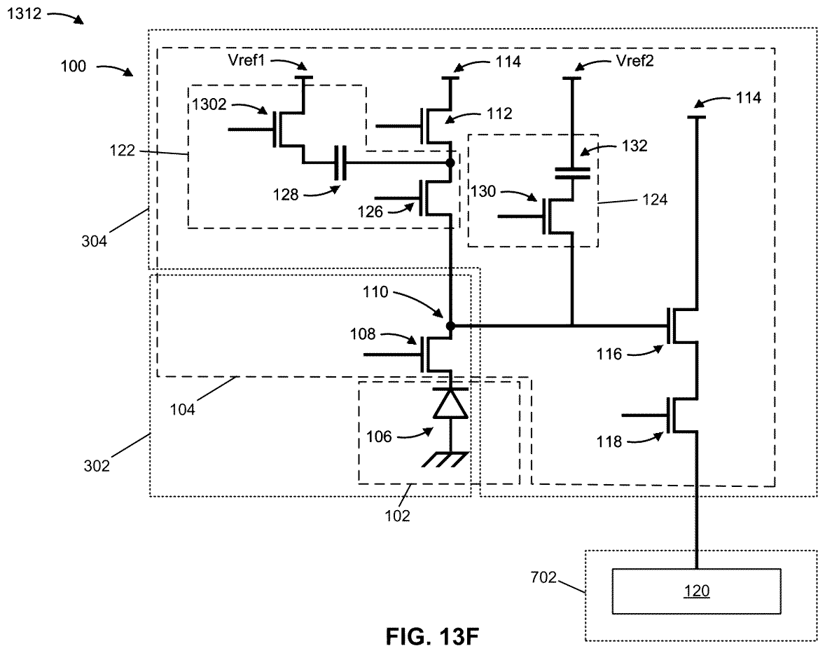

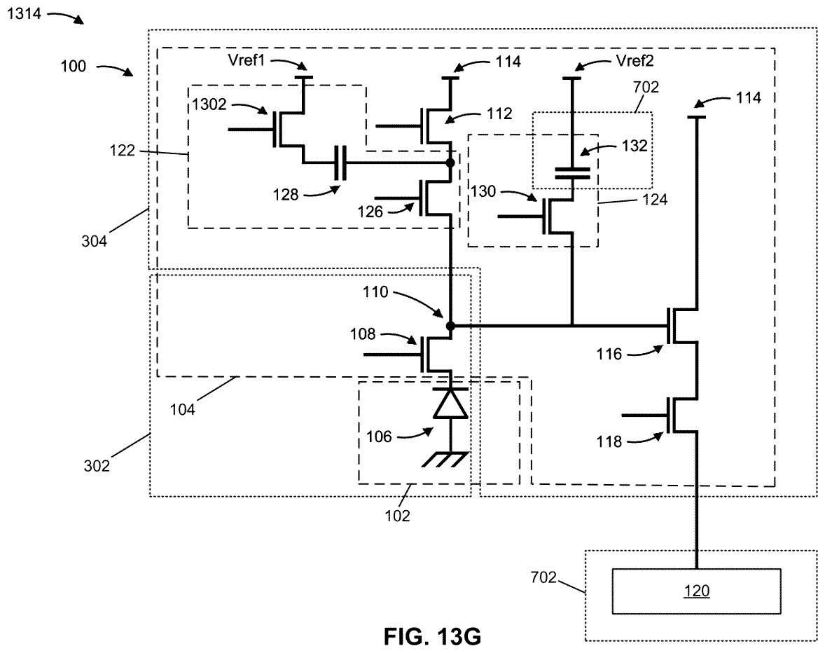

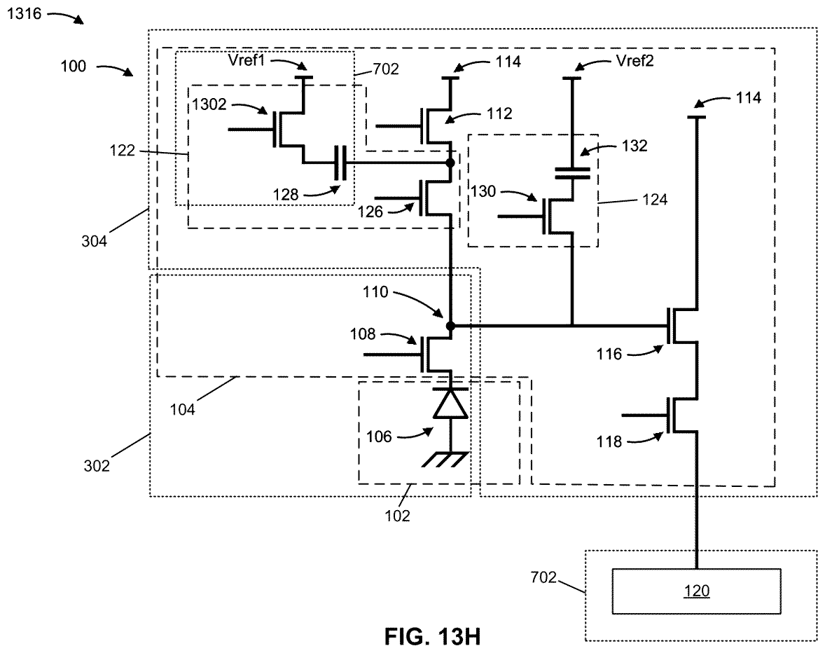

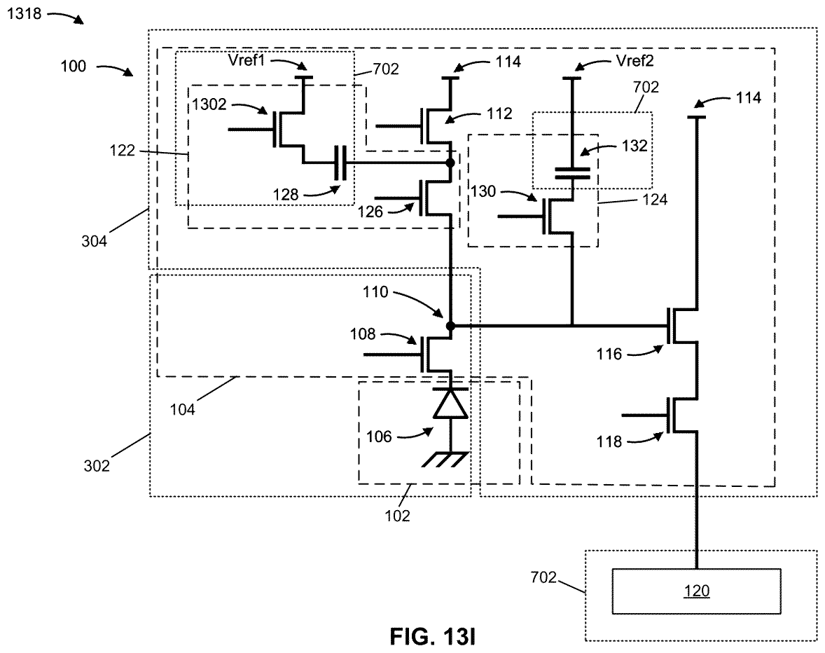

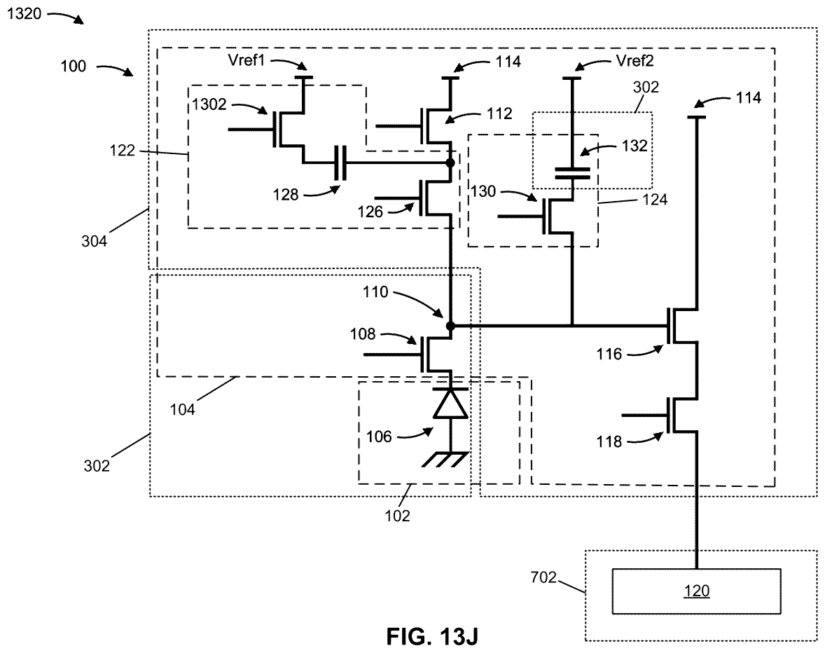

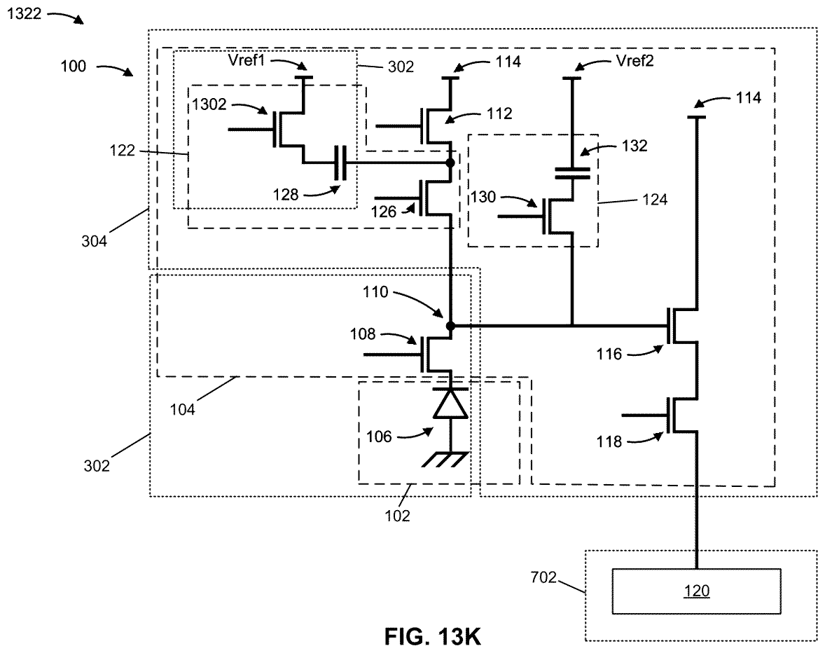

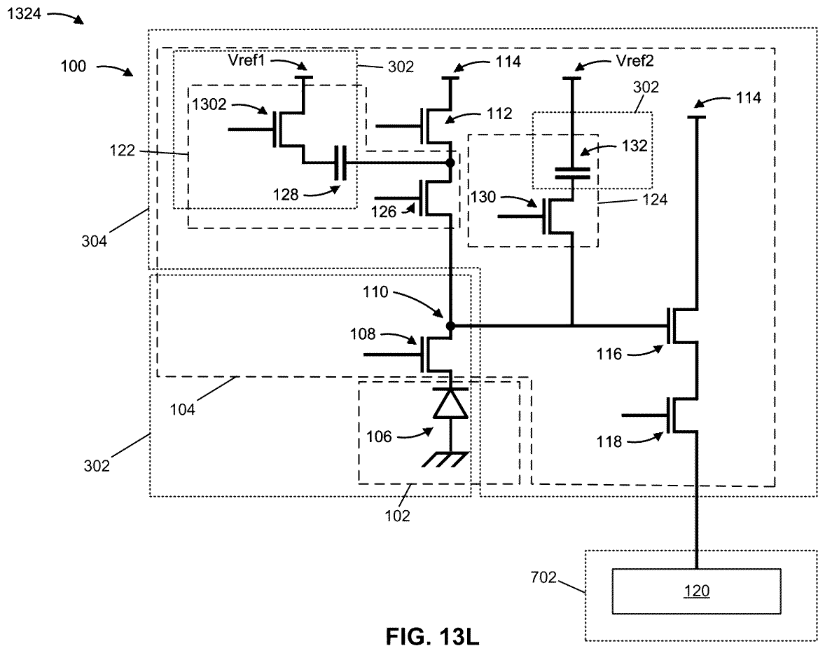

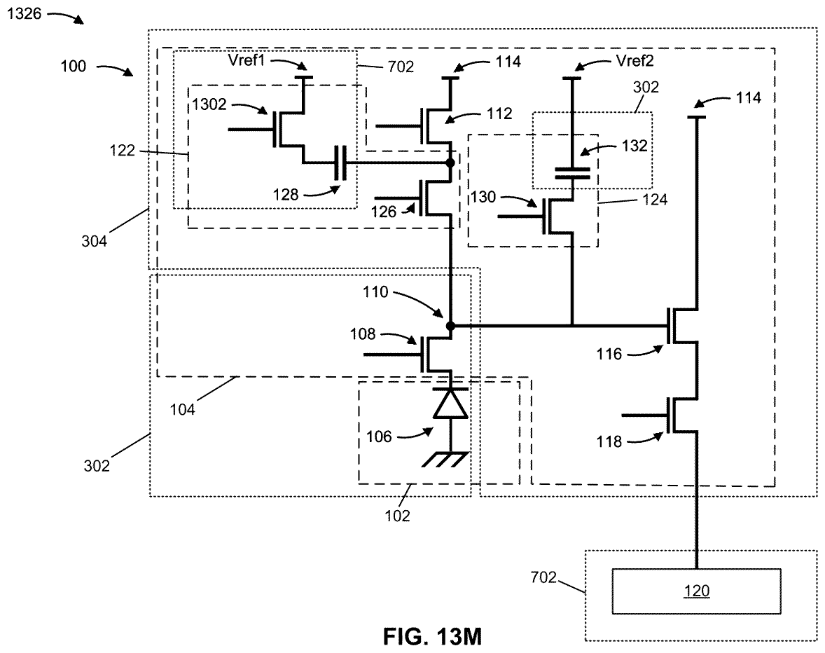

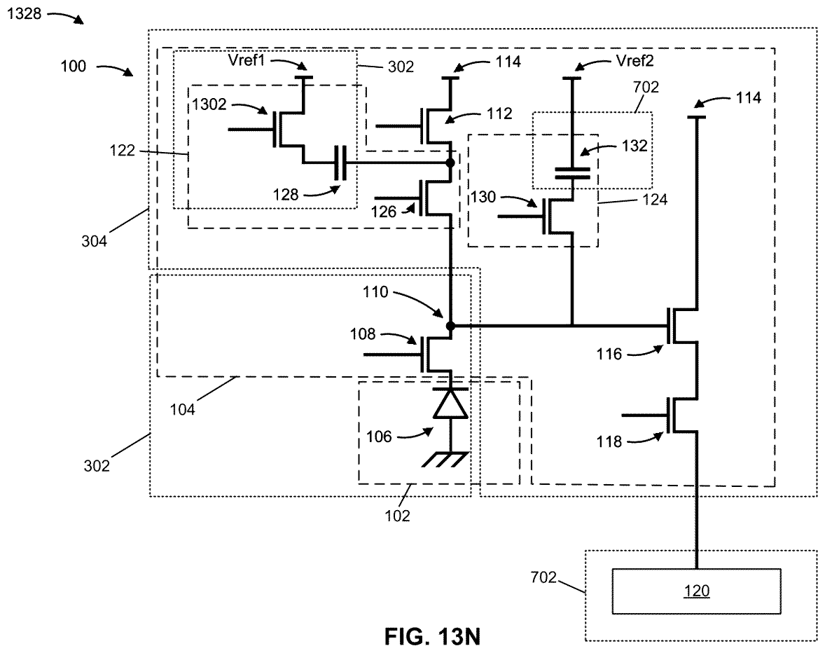

FIGS. 13A-13N are diagrams of examples of another example implementation 1300 of the pixel sensor 100 described herein. As shown in FIG. 13A, in the example implementation 1300, the pixel sensor 100 includes an additional transistor 1302 in the conversion gain circuit 122. The reset transistor 1302 may be activated, alone or in combination with the reset transistor 112, to reset the capacitor 128 of the conversion gain circuit 122. The use of the additional transistor 1302 to reset the capacitor 128 may enable the capacitor 128 to be reset faster, thereby reducing the reset time of the capacitor 128 and improving the responsiveness and speed of the pixel sensor 100.

To reset the capacitor 128, a voltage input may be applied to the gate of the transistor 1302 to activate the transistor 1302. The transistor 1302 induces a negative bias across the capacitor 128, where the voltage on the terminal of the capacitor 128 that is connected to the transistor 1302 is greater than the voltage on the terminal of the capacitor 128 that is connected to the reset transistor 112. This causes the charge stored in the capacitor 128 to be drained. The supply voltage source 114 may be biased low when the resist transistor 112 is off and the transistor 1302 is on, and the supply voltage 114 may be biased high when the resist transistor 112 is on and the reset transistor is off.

The transistors 1302 of the pixel sensors 100 described herein may be included on one or more semiconductor dies of a semiconductor device described herein. For example, as shown in an example implementation 1304 in FIG. 13B, the photodiode 106, the transfer gate 108, the floating diffusion node 110, the reset transistor 112, the source-follower transistor 116, the row-select transistor 118, the conversion gain transistor 126, the capacitor structure 128, the conversion gain transistor 130, the capacitor structure 132, and the transistor 1302 may be included on the semiconductor die 302 (e.g., a first semiconductor die), and the image processing circuit 120 may be included on the semiconductor die 304 (e.g., a second semiconductor die).

As another example, as shown in an example implementation 1306 in FIG. 13C, the photodiode 106, the transfer gate 108, the floating diffusion node 110, the reset transistor 112, the source-follower transistor 116, the row-select transistor 118, the conversion gain transistor 126, the capacitor structure 128, the conversion gain transistor 130, and the transistor 1302 may be included on the semiconductor die 302 (e.g., a first semiconductor die), and the image processing circuit 120 and the capacitor structure 132 may be included on the semiconductor die 304 (e.g., a second semiconductor die).

As another example, as shown in an example implementation 1308 in FIG. 13D, the photodiode 106, the transfer gate 108, the floating diffusion node 110, the reset transistor 112, the source-follower transistor 116, the row-select transistor 118, the conversion gain transistor 126, the conversion gain transistor 130, and the capacitor structure 132 may be included on the semiconductor die 302 (e.g., a first semiconductor die). The image processing circuit 120, the capacitor structure 128, and the transistor 1302 may be included on the semiconductor die 304 (e.g., a second semiconductor die).

As another example, as shown in an example implementation 1310 in FIG. 13E, the photodiode 106, the transfer gate 108, the floating diffusion node 110, the reset transistor 112, the source-follower transistor 116, the row-select transistor 118, the conversion gain transistor 126, and the conversion gain transistor 130 may be included on the semiconductor die 302 (e.g., a first semiconductor die). The image processing circuit 120, the capacitor structure 128, the capacitor structure 132, and the transistor 1302 may be included on the semiconductor die 304 (e.g., a second semiconductor die).

As another example, as shown in an example implementation 1312 in FIG. 13F, the photodiode 106, the transfer gate 108, and the floating diffusion node 110 may be included on the semiconductor die 302 (e.g., a first semiconductor die). The reset transistor 112, the source-follower transistor 116, the row-select transistor 118, the conversion gain transistor 126, the capacitor structure 128, the conversion gain transistor 130, the capacitor structure 132, and the transistor 1302 may be included on the semiconductor die 304 (e.g., a second semiconductor die). The image processing circuit 120 may be included on the semiconductor die 702 (e.g., a third semiconductor die).

As another example, as shown in an example implementation 1314 in FIG. 13G, the photodiode 106, the transfer gate 108, and the floating diffusion node 110 may be included on the semiconductor die 302 (e.g., a first semiconductor die). The reset transistor 112, the source-follower transistor 116, the row-select transistor 118, the conversion gain transistor 126, the capacitor structure 128, the conversion gain transistor 130, and the transistor 1302 may be included on the semiconductor die 304 (e.g., a second semiconductor die). The image processing circuit 120 and the capacitor structure 132 may be included on the semiconductor die 702 (e.g., a third semiconductor die).

As another example, as shown in an example implementation 1316 in FIG. 13H, the photodiode 106, the transfer gate 108, and the floating diffusion node 110 may be included on the semiconductor die 302 (e.g., a first semiconductor die). The reset transistor 112, the source-follower transistor 116, the row-select transistor 118, the conversion gain transistor 126, the conversion gain transistor 130, and the capacitor structure 132 may be included on the semiconductor die 304 (e.g., a second semiconductor die). The image processing circuit 120, the capacitor structure 128, and the transistor 1302 may be included on the semiconductor die 702 (e.g., a third semiconductor die).

As another example, as shown in an example implementation 1318 in FIG. 13I, the photodiode 106, the transfer gate 108, and the floating diffusion node 110 may be included on the semiconductor die 302 (e.g., a first semiconductor die). The reset transistor 112, the source-follower transistor 116, the row-select transistor 118, the conversion gain transistor 126, and the conversion gain transistor 130 may be included on the semiconductor die 304 (e.g., a second semiconductor die). The image processing circuit 120, the capacitor structure 128, the capacitor structure 132, and the transistor 1302 may be included on the semiconductor die 702 (e.g., a third semiconductor die).

As another example, as shown in an example implementation 1320 in FIG. 13J, the photodiode 106, the transfer gate 108, the floating diffusion node 110, and the capacitor structure 132 may be included on the semiconductor die 302 (e.g., a first semiconductor die). The reset transistor 112, the source-follower transistor 116, the row-select transistor 118, the conversion gain transistor 126, the capacitor structure 128, the conversion gain transistor 130, and the transistor 1302 may be included on the semiconductor die 304 (e.g., a second semiconductor die). The image processing circuit 120 may be included on the semiconductor die 702 (e.g., a third semiconductor die).

As another example, as shown in an example implementation 1322 in FIG. 13K, the photodiode 106, the transfer gate 108, the floating diffusion node 110, the capacitor structure 128, and the transistor 1302 may be included on the semiconductor die 302 (e.g., a first semiconductor die). The reset transistor 112, the source-follower transistor 116, the row-select transistor 118, the conversion gain transistor 126, the conversion gain transistor 130, and the capacitor structure 132 may be included on the semiconductor die 304 (e.g., a second semiconductor die). The image processing circuit 120 may be included on the semiconductor die 702 (e.g., a third semiconductor die).

As another example, as shown in an example implementation 1324 in FIG. 13L, the photodiode 106, the transfer gate 108, the floating diffusion node 110, the capacitor structure 128, the capacitor structure 132, and the transistor 1302 may be included on the semiconductor die 302 (e.g., a first semiconductor die). The reset transistor 112, the source-follower transistor 116, the row-select transistor 118, the conversion gain transistor 126, and the conversion gain transistor 130 may be included on the semiconductor die 304 (e.g., a second semiconductor die). The image processing circuit 120 may be included on the semiconductor die 702 (e.g., a third semiconductor die).

As another example, as shown in an example implementation 1326 in FIG. 13M, the photodiode 106, the transfer gate 108, the floating diffusion node 110, and the capacitor structure 132 may be included on the semiconductor die 302 (e.g., a first semiconductor die). The reset transistor 112, the source-follower transistor 116, the row-select transistor 118, the conversion gain transistor 126, and the conversion gain transistor 130 may be included on the semiconductor die 304 (e.g., a second semiconductor die). The image processing circuit 120, the capacitor structure 128, and the transistor 1302 may be included on the semiconductor die 702 (e.g., a third semiconductor die).

As another example, as shown in an example implementation 1328 in FIG. 13N, the photodiode 106, the transfer gate 108, the floating diffusion node 110, the capacitor structure 128, and the transistor 1302 may be included on the semiconductor die 302 (e.g., a first semiconductor die). The reset transistor 112, the source-follower transistor 116, the row-select transistor 118, the conversion gain transistor 126, and the conversion gain transistor 130 may be included on the semiconductor die 304 (e.g., a second semiconductor die). The image processing circuit 120, and the capacitor structure 132 may be included on the semiconductor die 702 (e.g., a third semiconductor die).

As indicated above, FIGS. 13A-13N are provided as examples. Other examples may differ from what is described with regard to FIGS. 13A-13N.

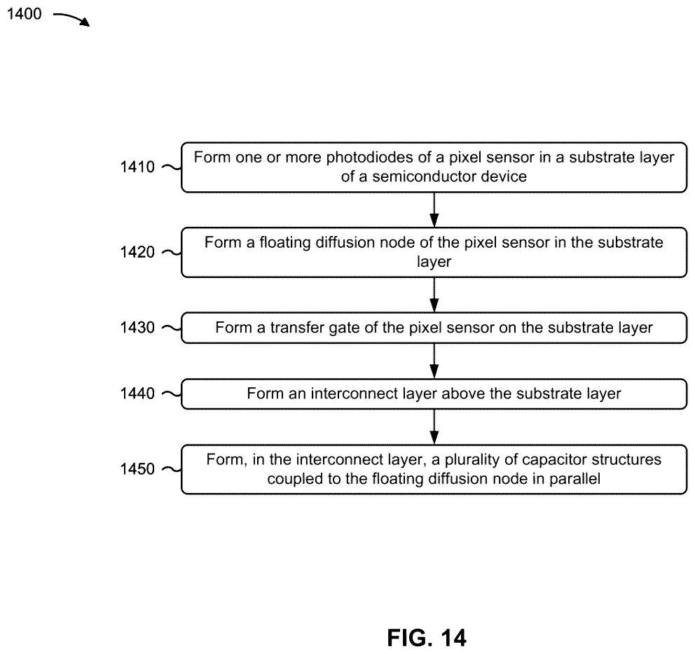

FIG. 14 is a flowchart of an example process 1400 associated with forming a semiconductor device described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming one or more photodiodes of a pixel sensor in a substrate layer of a semiconductor device (block 1410). For example, one or more semiconductor processing tools may be used to form one or more photodiodes (e.g., one or more photodiodes 106) of a pixel sensor (e.g., a pixel sensor 100) in a substrate layer (e.g., a substrate layer 318) of a semiconductor device (e.g., a semiconductor device 300, a semiconductor device 700, a semiconductor device 1200), as described herein.

As further shown in FIG. 14, process 1400 may include forming a floating diffusion node of the pixel sensor in the substrate layer (block 1420). For example, one or more semiconductor processing tools may be used to form a floating diffusion node (e.g., a floating diffusion node 110) of the pixel sensor in the substrate layer, as described herein.

As further shown in FIG. 14, process 1400 may include forming a transfer gate of the pixel sensor on the substrate layer (block 1430). For example, one or more semiconductor processing tools may be used to form a transfer gate (e.g., a transfer gate 108) of the pixel sensor on the substrate layer, as described herein.

As further shown in FIG. 14, process 1400 may include forming an interconnect layer above the substrate layer (block 1440). For example, one or more semiconductor processing tools may be used to form an interconnect layer (e.g., an interconnect layer 328) above the substrate layer, as described herein.

As further shown in FIG. 14, process 1400 may include forming, in the interconnect layer, a plurality of capacitor structures coupled to the floating diffusion node in parallel (block 1450). For example, one or more semiconductor processing tools may be used to form, in the interconnect layer, a plurality of capacitor structures (e.g., a capacitor 128, a capacitor 132) coupled to the floating diffusion node in parallel, as described herein.

Process 1400 may include additional implementations, such as any single implementation or any combination of implementations described below and/or in connection with one or more other processes described elsewhere herein.

In a first implementation, forming the plurality of capacitor structures includes forming a first capacitor structure (e.g., a capacitor 128) having a first capacitance (e.g., a capacitance C1), and forming a second capacitor structure (e.g., a capacitor 132) having a second capacitance (e.g., a capacitance C2), wherein the first capacitance and the second capacitance are different capacitances.

In a second implementation, alone or in combination with the first implementation, the first capacitance is greater than the second capacitance.

In a third implementation, alone or in combination with one or more of the first and second implementations, process 1400 includes forming a first transistor (e.g., a conversion gain transistor 126) in the substrate layer of the semiconductor device, where a first capacitor structure (e.g., a capacitor 128) of the plurality of capacitor structures is coupled to the first transistor, and forming a second transistor (e.g., a conversion gain transistor 130) in the substrate layer of the semiconductor device, where a second capacitor structure (e.g., a capacitor 132) of the plurality of capacitor structures is coupled to the second transistor.

In a fourth implementation, alone or in combination with one or more of the first through third implementations, process 1400 includes forming a third transistor (e.g., a reset transistor 112) to the first capacitor structure, and forming a fourth transistor (e.g., a transistor 1302) coupled to the first capacitor structure, where the first and second reset transistors are coupled to the first capacitor structure in parallel.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

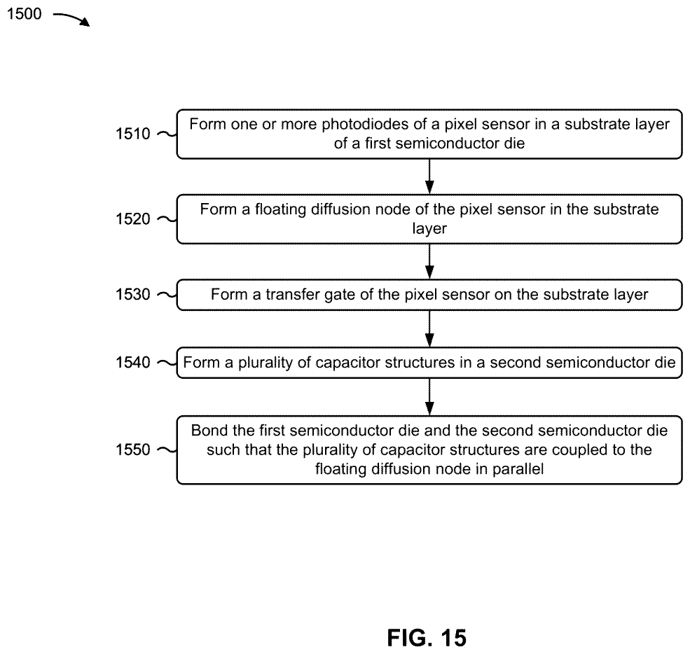

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming one or more photodiodes of a pixel sensor in a substrate layer of a first semiconductor die (block 1510). For example, one or more semiconductor processing tools may be used to form one or more photodiodes (e.g., one or more photodiodes 106) of a pixel sensor (e.g., a pixel sensor 100) in a substrate layer (e.g., a substrate layer 318) of a first semiconductor die (e.g., a semiconductor die 302), as described herein.

As further shown in FIG. 15, process 1500 may include forming a floating diffusion node of the pixel sensor in the substrate layer (block 1520). For example, one or more semiconductor processing tools may be used to form a floating diffusion node (e.g., a floating diffusion node 110) of the pixel sensor in the substrate layer, as described herein.

As further shown in FIG. 15, process 1500 may include forming a transfer gate of the pixel sensor on the substrate layer (block 1530). For example, one or more semiconductor processing tools may be used to form a transfer gate (e.g., a transfer gate 108) of the pixel sensor on the substrate layer, as described herein.

As further shown in FIG. 15, process 1500 may include forming a plurality of capacitor structures in a second semiconductor die (block 1540). For example, one or more semiconductor processing tools may be used to form a plurality of capacitor structures (e.g., a capacitor 128, a capacitor 132) in a second semiconductor die (e.g., a semiconductor die 304), as described herein.

As further shown in FIG. 15, process 1500 may include bonding the first semiconductor die and the second semiconductor die such that the plurality of capacitor structures are coupled to the floating diffusion node in parallel (block 1550). For example, one or more semiconductor processing tools may be used to bond the first semiconductor die and the second semiconductor die such that the plurality of capacitor structures are coupled to the floating diffusion node in parallel, as described herein.

Process 1500 may include additional implementations, such as any single implementation or any combination of implementations described below and/or in connection with one or more other processes described elsewhere herein.

In a first implementation, process 1500 includes forming a first conversion gain transistor (e.g., a conversion gain transistor 126) in a substrate layer (e.g., a substrate layer 342) of the second semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor.

In a second implementation, alone or in combination with the first implementation, forming the first capacitor structure includes forming the first capacitor structure in the substrate layer of the second semiconductor die, and forming the second capacitor structure includes forming the second capacitor structure in the substrate layer of the second semiconductor die.

In a third implementation, alone or in combination with one or more of the first and second implementations, forming the first capacitor structure includes forming the first capacitor structure in the substrate layer of the second semiconductor die, and forming the second capacitor structure includes forming the second capacitor structure in an interconnect layer of the second semiconductor die above the substrate layer of the second semiconductor die.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

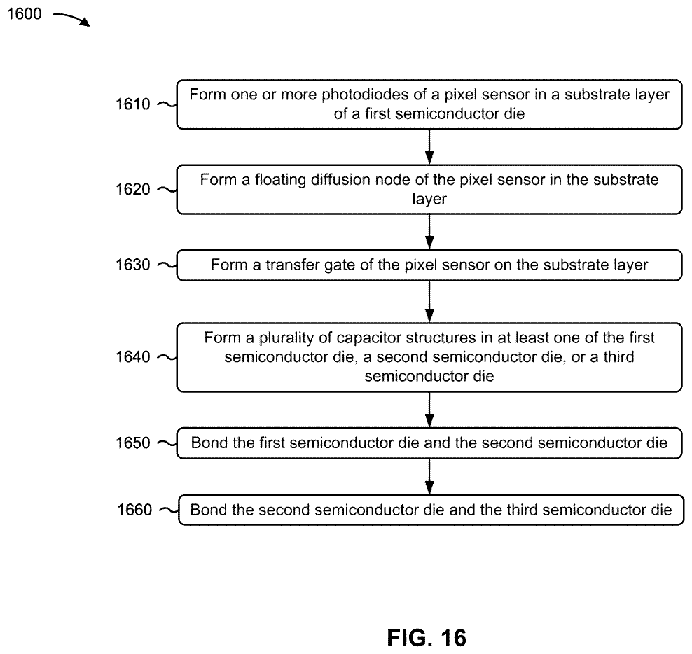

FIG. 16 is a flowchart of an example process 1600 associated with forming a semiconductor device described herein. In some implementations, one or more process blocks of FIG. 16 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 16, process 1600 may include forming one or more photodiodes of a pixel sensor in a substrate layer of a first semiconductor die (block 1610). For example, one or more semiconductor processing tools may be used to form one or more photodiodes (e.g., one or more photodiodes 106) of a pixel sensor (e.g., a pixel sensor 100) in a substrate layer (e.g., a substrate layer 318) of a first semiconductor die (e.g., a semiconductor die 302), as described herein.

As further shown in FIG. 16, process 1600 may include forming a floating diffusion node of the pixel sensor in the substrate layer (block 1620). For example, one or more semiconductor processing tools may be used to form a floating diffusion node (e.g., a floating diffusion node 110) of the pixel sensor in the substrate layer, as described herein.

As further shown in FIG. 16, process 1600 may include forming a transfer gate of the pixel sensor on the substrate layer (block 1630). For example, one or more semiconductor processing tools may be used to form a transfer gate (e.g., a transfer gate 108) of the pixel sensor on the substrate layer, as described herein.

As further shown in FIG. 16, process 1600 may include forming a plurality of capacitor structures in at least one of the first semiconductor die, a second semiconductor die, or a third semiconductor die (block 1640). For example, one or more semiconductor processing tools may be used to form a plurality of capacitor structures (e.g., a capacitor 128, a capacitor 132) in at least one of the first semiconductor die, a second semiconductor die (e.g., a semiconductor die 304), or a third semiconductor die (e.g., a semiconductor die 702), as described herein.

As further shown in FIG. 16, process 1600 may include bonding the first semiconductor die and the second semiconductor die (block 1650). For example, one or more semiconductor processing tools may be used to bond the first semiconductor die and the second semiconductor die, as described herein.

As further shown in FIG. 16, process 1600 may include bonding the second semiconductor die and the third semiconductor die (block 1660). For example, one or more semiconductor processing tools may be used to bond the second semiconductor die and the third semiconductor die, as described herein. In some implementations, the plurality of capacitor structures are coupled to the floating diffusion node in parallel.

Process 1600 may include additional implementations, such as any single implementation or any combination of implementations described below and/or in connection with one or more other processes described elsewhere herein.

In a first implementation, process 1600 includes forming a first conversion gain transistor (e.g., a conversion gain transistor 126) in the substrate layer of the first semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor, and where forming the plurality of capacitor structures includes forming the first capacitor structure in the first semiconductor die or in the second semiconductor die, and forming the second capacitor structure in a same semiconductor die as the first capacitor structure.

In a second implementation, along or in combination with the first implementation, process 1600 includes forming a first conversion gain transistor (e.g., a conversion gain transistor 126) in the substrate layer of the first semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor, and where forming the plurality of capacitor structures includes forming the first capacitor structure in the first semiconductor die or in the second semiconductor die, and forming the second capacitor structure in a different semiconductor die than the first capacitor structure.

In a third implementation, alone or in combination with the first or second implementation, process 1600 includes forming a first conversion gain transistor (e.g., a conversion gain transistor 126) in a substrate layer (e.g., a substrate layer 342) of the second semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor, and where forming the plurality of capacitor structures includes forming the first capacitor structure in the first semiconductor die or in the second semiconductor die, and forming the second capacitor structure in the first semiconductor die or the second semiconductor die.

In a fourth implementation, alone in combination with one or more of the first through third implementations, process 1600 includes forming a first conversion gain transistor (e.g., a conversion gain transistor 126) in a substrate layer (e.g., a substrate layer 342) of the second semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor, and where forming the plurality of capacitor structures includes forming the first capacitor structure in the first semiconductor die or in the third semiconductor die, and forming the second capacitor structure in the first semiconductor die or the third semiconductor die.

In a fifth implementation, alone or in combination with one or more of the first through fourth implementations, process 1600 includes forming a first conversion gain transistor (e.g., a conversion gain transistor 126) in a substrate layer (e.g., a substrate layer 342) of the second semiconductor die, where a first capacitor structure (e.g., a capacitor 128) of the plurality of capacitor structures is coupled to the first conversion gain transistor, and forming a second conversion gain transistor (e.g., a conversion gain transistor 130) in the substrate layer of the second semiconductor die, where a second capacitor structure (e.g., a capacitor 132) of the plurality of capacitor structures is coupled to the second conversion gain transistor, and where forming the plurality of capacitor structures includes forming the first capacitor structure in the second semiconductor die or in the second semiconductor die, and forming the second capacitor structure in the second semiconductor die or the second semiconductor die.

Although FIG. 16 shows example blocks of process 1500, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, a control circuitry region of a pixel sensor of a semiconductor device includes a plurality of conversion gain circuits that may be selectively activated and/or deactivated in various combinations to enable a plurality of sequential conversion gain operations to be performed across an exposure operation of the semiconductor device. The control circuitry region may include a first conversion gain circuit and a second conversion gain circuit that are connected to a floating diffusion node of the pixel sensor in parallel. The selectable parallel conversion gain circuits enable sequential conversion gain operations to be performed for the pixel sensor such that the capacitance in the pixel sensor may be gradually increased through the conversion gain operations. Gradually increasing the capacitance in the pixel sensor across the sequential conversion gain operations provides for smaller SNR drops, which enables a low SNR drop to be achieved in a composite pixel sensor signal that is generated from the sequential conversion gain operations. The low SNR drop may enable reduced noise in images and/or video generated by the semiconductor device to be achieved, which increases the quality of the images and/or video generated by the semiconductor device.

As described in greater detail above, some implementations described herein provide a semiconductor device. The semiconductor device includes a pixel sensor. The pixel sensor includes one or more photodiodes, a transfer gate coupled to the one or more photodiodes, a floating diffusion node coupled to the transfer gate, and a plurality of capacitor structures coupled to the floating diffusion node in parallel.

As described in greater detail above, some implementations described herein provide a method. The method includes forming one or more photodiodes of a pixel sensor in a substrate layer of a semiconductor device. The method includes forming a floating diffusion node of the pixel sensor in the substrate layer. The method includes forming a transfer gate of the pixel sensor on the substrate layer. The method includes forming an interconnect layer above the substrate layer. The method includes forming, in the interconnect layer, a plurality of capacitor structures coupled to the floating diffusion node in parallel.

As described in greater detail above, some implementations described herein provide a method. The method includes forming one or more photodiodes of a pixel sensor in a substrate layer of a first semiconductor die. The method includes forming a floating diffusion node of the pixel sensor in the substrate layer. The method includes forming a transfer gate of the pixel sensor on the substrate layer. The method includes forming a plurality of capacitor structures in a second semiconductor die. The method includes bonding the first semiconductor die and the second semiconductor die such that the plurality of capacitor structures are coupled to the floating diffusion node in parallel.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a pixel sensor, comprising:
one or more photodiodes; and
a transfer gate coupled to the one or more photodiodes;
a floating diffusion node coupled to the transfer gate; and
a plurality of capacitor structures coupled to the floating diffusion node in parallel.

2. The semiconductor device of claim 1, wherein the pixel sensor further comprises:
a first transistor structure coupled to the floating diffusion node and to a first capacitor structure of the plurality of capacitor structures; and
a second transistor structure coupled to the floating diffusion node and to a second capacitor structure of the plurality of capacitor structures.

3. The semiconductor device of claim 2, wherein a first capacitance of the first capacitor structure is greater than a second capacitance of the second capacitor structure are different capacitances.

4. The semiconductor device of claim 2, wherein a first source/drain terminal of the first transistor structure is coupled to the floating diffusion node;
wherein a second source/drain terminal of the first transistor structure is coupled to the first capacitor structure;
wherein a third source/drain terminal of the second transistor structure is coupled to the floating diffusion node; and
wherein a fourth source/drain terminal of the second transistor structure is coupled to the second capacitor structure.

5. The semiconductor device of claim 1, wherein the plurality of capacitor structures are coupled to a source-follower gate of the pixel sensor in parallel.

6. The semiconductor device of claim 1, wherein the one or more photodiodes and the plurality of capacitor structures are included on a same semiconductor die of the semiconductor device.

7. The semiconductor device of claim 1, wherein the one or more photodiodes is included on a first semiconductor die) of the semiconductor device; and
wherein the plurality of capacitor structures are included on at least one of the first semiconductor die or a second semiconductor die) of the semiconductor device.

8. The semiconductor device of claim 1, wherein the floating diffusion node and the plurality of capacitor structures are included on a same semiconductor die of the semiconductor device.

9. The semiconductor device of claim 1, wherein the floating diffusion node is included on a first semiconductor die of the semiconductor device; and
wherein the plurality of capacitor structures are included on a second semiconductor die of the semiconductor device.

10. The semiconductor device of claim 1, wherein a first portion of the floating diffusion node is included on a first semiconductor die of the semiconductor device;
wherein a second portion of the floating diffusion node is included on a second semiconductor die of the semiconductor device; and
wherein the plurality of capacitor structures are included on the second semiconductor die.

11. A method, comprising:
forming one or more photodiodes of a pixel sensor in a substrate layer of a semiconductor device;
forming a floating diffusion node of the pixel sensor in the substrate layer;
forming a transfer gate of the pixel sensor on the substrate layer;
forming an interconnect layer above the substrate layer; and
forming, in the interconnect layer, a plurality of capacitor structures coupled to the floating diffusion node in parallel.

12. The method of claim 11, wherein forming the plurality of capacitor structures comprises:
forming a first capacitor structure having a first capacitance; and
forming a second capacitor structure having a second capacitance,
wherein the first capacitance is greater than the second capacitance.

13. The method of claim 11, further comprising:
forming a first transistor in the substrate layer of the semiconductor device,
wherein a first capacitor structure of the plurality of capacitor structures is coupled to the first transistor; and
forming a second transistor in the substrate layer of the semiconductor device,
wherein a second capacitor structure of the plurality of capacitor structures is coupled to the second transistor.

14. The method of claim 13, further comprising:
forming a third transistor coupled to a first terminal of the first capacitor structure; and
forming a fourth transistor coupled to a second terminal of the first capacitor structure.

15. A method, comprising:
forming one or more photodiodes of a pixel sensor in a substrate layer of a first semiconductor die;
forming a floating diffusion node of the pixel sensor in the substrate layer;
forming a transfer gate of the pixel sensor on the substrate layer;
forming a plurality of capacitor structures in at least one of the first semiconductor die, a second semiconductor die, or a third semiconductor die;
bonding the first semiconductor die and the second semiconductor die together; and
bonding the second semiconductor die and the third semiconductor die together,
wherein the plurality of capacitor structures are coupled to the floating diffusion node in parallel.

16. The method of claim 15, further comprising:
forming a first conversion gain transistor in the substrate layer of the first semiconductor die,
wherein a first capacitor structure of the plurality of capacitor structures is coupled to the first conversion gain transistor; and
forming a second conversion gain transistor in the substrate layer of the first semiconductor die,
wherein a second capacitor structure of the plurality of capacitor structures is coupled to the second conversion gain transistor, and
wherein forming the plurality of capacitor structures comprises:
forming the first capacitor structure in the first semiconductor die or in the second semiconductor die; and
forming the second capacitor structure in a different semiconductor die than the first capacitor structure.

17. The method of claim 15, further comprising:
forming a first conversion gain transistor in the substrate layer of the first semiconductor die,
wherein a first capacitor structure of the plurality of capacitor structures is coupled to the first conversion gain transistor; and
forming a second conversion gain transistor in the substrate layer of the first semiconductor die,
wherein a second capacitor structure of the plurality of capacitor structures is coupled to the second conversion gain transistor, and
wherein forming the plurality of capacitor structures comprises:
forming the first capacitor structure in the first semiconductor die or in the second semiconductor die; and
forming the second capacitor structure in a same semiconductor die as the first capacitor structure.

18. The method of claim 15, further comprising:
forming a first conversion gain transistor in another substrate layer of the second semiconductor die,
wherein a first capacitor structure of the plurality of capacitor structures is coupled to the first conversion gain transistor; and
forming a second conversion gain transistor in the substrate layer of the second semiconductor die,
wherein a second capacitor structure of the plurality of capacitor structures is coupled to the second conversion gain transistor, and
wherein forming the plurality of capacitor structures comprises:
forming the first capacitor structure in the first semiconductor die or in the second semiconductor die; and
forming the second capacitor structure in the first semiconductor die or in the second semiconductor die.

19. The method of claim 15, further comprising:
forming a first conversion gain transistor in another substrate layer of the second semiconductor die,
wherein a first capacitor structure of the plurality of capacitor structures is coupled to the first conversion gain transistor; and
forming a second conversion gain transistor in the substrate layer of the second semiconductor die,
wherein a second capacitor structure of the plurality of capacitor structures is coupled to the second conversion gain transistor, and
wherein forming the plurality of capacitor structures comprises:
forming the first capacitor structure in the first semiconductor die or in the third semiconductor die; and
forming the second capacitor structure in the first semiconductor die or in the third semiconductor die.

20. The method of claim 15, further comprising:
forming a first conversion gain transistor in another substrate layer of the second semiconductor die,
wherein a first capacitor structure of the plurality of capacitor structures is coupled to the first conversion gain transistor; and
forming a second conversion gain transistor in the substrate layer of the second semiconductor die,
wherein a second capacitor structure of the plurality of capacitor structures is coupled to the second conversion gain transistor, and
wherein forming the plurality of capacitor structures comprises:
forming the first capacitor structure in the second semiconductor die or in the third semiconductor die; and
forming the second capacitor structure in the second semiconductor die or in the third semiconductor die.
